(19) United States
(12) Patent Application Publication
(10) Pub. No.: US 2023/0314945 A1
(43) Pub. Date: Oct. 5, 2023

(54) NEGATIVE-TONE RESIST COMPOSITION AND METHOD OF FORMING RESIST PATTERN

(71) Applicant: TOKYO OHKA KOGYO CO., LTD., Kawasaki-shi (JP)

(72) Inventors: Keiichi IBATA, Kawasaki-shi (JP); Masaru TAKESHITA, Kawasaki-shi (JP); Tomotaka YAMADA, Kawasaki-shi (JP)

(21) Appl. No.: 18/190,714

(22) Filed: Mar. 27, 2023

(30) Foreign Application Priority Data
Mar. 29, 2022 (JP) 2022-054106

(51) Int. Cl. G03F 7/075

(52) U.S. Cl. CPC G03F 7/0757

(57) ABSTRACT

A negative-tone resist composition containing a silicon-containing resin, an acid generator component that generates acid upon exposure, and a crosslinking agent component. The silicon-containing resin (A) contains a silicon-containing polymer having a phenolic hydroxyl group, and the acid generator component contains a sulfonium salt having a fluorine atom in a cation moiety.

### BACKGROUND OF THE INVENTION

### Field of the Invention

The present invention relates to a negative-tone resist composition and a method of forming a resist pattern.

Priority is claimed on Japanese Patent Application No. 2022-054106, filed on Mar. 29, 2022, the content of which is incorporated herein by reference.

### Description of Related Art

In the manufacture of electronic components, processing including etching is carried out on a laminate in which a resist film is formed on a substrate such as a silicon wafer using a resist material. For example, a resist pattern is formed on a resist film by selectively exposing the resist film, and dry etching is carried out using the resist film as a mask to form a pattern on the substrate.

In recent years, in the production of semiconductor elements and liquid crystal display elements, with advances in lithography techniques, rapid progress in the field of pattern fining has been achieved. In general, the pattern fining method involves shortening the wavelength (increasing the energy) of the light source for exposure.

Resist materials have been required to have lithography characteristics such as sensitivity to these light sources for exposure and resolution capable of reproducing a fine-sized pattern.

As a resist material that satisfies these requirements, a chemical amplification-type resist composition that contains a base material component having solubility in a developing solution, which is changed under action of acid, and an acid generator component that generates acid upon exposure has been conventionally used in the related art.

In the chemical amplification-type resist composition, a resin having a plurality of constitutional units is generally used in order to improve lithography characteristics.

In addition, as the resist material, a material having etching resistance is required in order to fulfill the function as a mask for substrate processing. On the other hand, a silicon-containing polymer is usually used as a base material component.

For example, in order to cope with pattern fining, Patent Document 1 discloses a negative-tone resist composition that contains a silsesquioxane resin having two specific constitutional units, an acid generator component, and a crosslinking agent component.

### CITATION LIST

[Patent Document]
[Patent Document] PCT International Publication No. WO2005/091073

### SUMMARY OF THE INVENTION

With the further pattern fining, the thickness of the resist film has been reduced, and resist materials are further required to be improved in various lithography characteristics such as high sensitivity at the time of the resist pattern formation and reduction of linewise roughness (LWR: non-uniformity of line width) in a case of a line pattern.

The present invention has been made in consideration of the above circumstances, and an object of the present invention is to provide a negative-tone resist composition and a method of forming a resist pattern, which makes it possible to achieve high sensitivity and form a further fine-sized pattern having a good shape.

In order to achieve the above-described object, the present invention employs the following configurations.

That is, a first aspect of the present invention is a negative-tone resist composition characterized by containing a silicon-containing resin (A), an acid generator component (B) that generates acid upon exposure, and a crosslinking agent component (C), in which the silicon-containing resin (A) contains a silicon-containing polymer (A1) having a phenolic hydroxyl group, and the acid generator component (B) contains a sulfonium salt (B1) having a fluorine atom in a cation moiety.

The second aspect of the present invention is a method of forming a resist pattern characterized by including a step (i) of forming a resist film on a support using the negative-tone resist composition according to the first aspect, a step (ii) of exposing the resist film, and a step (iii) of developing the exposed resist film to form a negative-tone resist pattern.

According to the present invention, it is possible to provide a negative-tone resist composition and a method of forming a resist pattern, which makes it possible to achieve high sensitivity and form a further fine-sized pattern having a good shape.

### DETAILED DESCRIPTION OF THE INVENTION

In the present specification and the scope of the present patent claims, the term “aliphatic” is a relative concept used with respect to the term “aromatic” and defines a group or compound that has no aromaticity.

The “alkyl group” includes a monovalent saturated hydrocarbon group that is linear, branched, or cyclic, unless otherwise specified. The same applies to the alkyl group of the alkoxy group.

The “alkylene group” includes a divalent saturated hydrocarbon group that is linear, branched, or cyclic, unless otherwise specified.

Examples of the “halogen atom” include a fluorine atom, a chlorine atom, a bromine atom, and an iodine atom.

The term “constitutional unit” means a monomer unit (monomeric unit) that constitutes a polymeric compound (a resin, a polymer, or a copolymer).

In a case where “may have a substituent” is described, both of a case where a hydrogen atom (—H) is substituted with a monovalent group and a case where a methylene group (—CH₂—) is substituted with a divalent group are included.

The “exposure” is used as a general concept that includes irradiation with active energy rays such as an ultraviolet ray, a radiation, and an electron beam.

The “acid decomposable group” indicates a group in which at least part of bonds in the structure of the acid decomposable group can be cleaved under action of acid.

Examples of the acid decomposable group having a polarity that is increased under action of acid include groups which is decomposed under action of acid to generate a polar group.

Examples of the polar group include a carboxy group, a hydroxyl group, an amino group, and a sulfo group (—SO₃H).

More specific examples of the acid decomposable group include a group (for example, a group obtained by protecting a hydrogen atom of the OH-containing polar group with an acid dissociable group) obtained by protecting the above-described polar group with an acid dissociable group.

The term “acid dissociable group” indicates any one of (i) a group in which a bond between the acid dissociable group and an atom adjacent to the acid dissociable group can be cleaved under action of acid; and (ii) a group in which part of bonds are cleaved under action of acid, and then a decarboxylation reaction occurs, thereby cleaving the bond between the acid dissociable group and the atom adjacent to the acid dissociable group.”

It is necessary that the acid dissociable group that constitutes the acid decomposable group be a group that exhibits a lower polarity than the polar group generated by the dissociation of the acid dissociable group. Thus, in a case where the acid dissociable group is dissociated under action of acid, a polar group that exhibits a higher polarity than the acid dissociable group is generated, thereby increasing the polarity. As a result of the above, the polarity of the entire components having this acid dissociable group is increased. With the increase in the polarity, the solubility in a developing solution relatively changes. The solubility in a developing solution is increased in a case where the developing solution is an alkali developing solution, whereas the solubility in a developing solution is decreased in a case where the developing solution is an organic developing solution.

The term “base material component” is an organic compound having a film-forming ability. The organic compounds used as the base material component are roughly classified into a non-polymer and a polymer. As the non-polymer, those having a molecular weight of 500 or more and less than 4,000 are usually used. Hereinafter, a “low molecular weight compound” refers to a non-polymer having a molecular weight of 500 or more and less than 4,000. As the polymer, those having a molecular weight of 1,000 or more are usually used. Hereinafter, a “resin”, a “polymeric compound”, or a “polymer” refers to a polymer having a molecular weight of 1,000 or more. As the molecular weight of the polymer, a weight average molecular weight in terms of the polystyrene equivalent value determined by gel permeation chromatography (GPC) is used.

The term “constitutional unit derived from” means a constitutional unit that is formed by the cleavage of a multiple bond between carbon atoms, for example, an ethylenic double bond.

The term “derivative” is used as a concept that includes a compound obtained by substituting a hydrogen atom at the α-position of an object compound with another substituent such as an alkyl group or a halogenated alkyl group; and a derivative thereof. Examples of the derivatives thereof include a derivative in which the hydrogen atom of the hydroxyl group of the object compound in which the hydrogen atom at the α-position may be substituted with a substituent is substituted with an organic group; and a derivative in which a substituent other than a hydroxyl group is bonded to the object compound in which the hydrogen atom at the α-position may be substituted with a substituent. The α-position refers to the first carbon atom adjacent to the functional group unless otherwise specified.

Examples of the substituent that is substituted for the hydrogen atom at the α-position of hydroxystyrene include the same one as R^{αx}.

In the present specification and the scope of the present patent claims, asymmetric carbon atoms may be present, and thus enantiomers or diastereomers may be present depending on the structures represented by the chemical formula. In that case, these isomers are represented by one chemical formula. These isomers may be used alone or in the form of a mixture.

(Negative-Tone Resist Composition)

The negative-tone resist composition according to the first aspect of the present invention contains a silicon-containing resin (A) (hereinafter, also referred to as a “component (A)”), an acid generator component (B) that generates acid upon exposure (hereinafter, also referred to as a “component (B)”), and a crosslinking agent component (C) (hereinafter, also referred to as a “component (C)”).

In the negative-tone resist composition according to the present aspect, the component (A) contains a silicon-containing polymer (A1) having a phenolic hydroxyl group. The component (B) contains a sulfonium salt (B1) having a fluorine atom in the cation moiety.

In one embodiment of the negative-tone resist composition, in a case where acid is generated from the component (B) upon exposure, this acid acts on the component (C) to exhibit reduced solubility in a developing solution due to a crosslinking reaction. As a result, in the formation of the resist pattern, in a case where a resist film obtained by applying the negative-tone resist composition onto a support is selectively exposed, exposed portions of the resist film exhibit reduced solubility in a developing solution, whereas unexposed portions of the resist film do not exhibit changed solubility in a developing solution, which results in a difference in solubility in the developing solution between the exposed portions and the unexposed portions of the resist film. As a result, in a case where the resist film is subjected to alkali development or solvent development, unexposed portions of the resist film are dissolved and removed to form a negative-tone resist pattern. This makes it possible to form a desired resist pattern with high accuracy by carrying out selective exposure through a desired mask pattern.

Further, in the formation of a resist pattern, the negative-tone resist composition according to the present embodiment may be applied to an alkali developing process using an alkali developing solution in the developing treatment at the time of the resist pattern formation, or a solvent developing process using a developing solution (an organic developing solution) containing an organic solvent in the developing treatment. The negative-tone resist composition according to the present embodiment is particularly useful for an alkali developing process.

<Silicon-Containing Resin (A)>

The component (A) that is used in the negative-tone resist composition according to the present embodiment contains a silicon-containing polymer (A1) having a phenolic hydroxyl group (hereinafter, also referred to as a “component (A1)”).

In the negative-tone resist composition according to the present embodiment, the resin containing silicon (Si) is contained, and thus, in particular, the etching resistance of the resist film that is formed from the negative-tone resist composition is enhanced.

The content proportion of the silicon (Si) in the component (A) is preferably 5% to 50% with respect to the total amount of all atoms constituting the component (A).

The silicon content proportion in the component (A) can be calculated according to the following expression.

The silicon content proportion (%)=(the number of silicon atoms present in the silicon-containing resin×the atomic weight of silicon)/(the total atomic weight calculated by multiplying the number of atoms of each atom constituting the silicon-containing resin by each atomic weight and summing each value obtained)×100

For example, in a case of a polysiloxane consisting of a repeating structure of a constitutional unit represented by —[Si(H)O_{3/2}]—, the silicon content proportion is, {(28×1)×100}/[{(28×1)+(16×1.5)+(1×1)}×100]≈52.8%.

Examples of such a component (A) include resins that are soluble in an alkali developing solution and have a crosslinkable group, where a polysiloxane is preferable. Among these, it is more preferable to contain a silsesquioxane resin. Here, the silsesquioxane resin may have a ladder-type structure or a cage-type structure.

<<Silicon-Containing Polymer (A1) Having a Phenolic Hydroxyl Group>>

The component (A1) is a silicon-containing polymer having a phenolic hydroxyl group and has a phenolic hydroxyl group and silicon in the same polymer, and preferred examples thereof include a polysiloxane having a main chain consisting of a siloxane bond and a side chain containing a phenolic hydroxyl group.

Examples of such a component (A1) include a polysiloxane in which the polymer main chain consists of a repeating structure of an Si—O bond and which has a constitutional unit (a1) containing a phenolic hydroxyl group.

Constitutional Unit (a1)

The constitutional unit (a1) is a constitutional unit containing a phenolic hydroxyl group.

Examples of the constitutional unit (a1) include those in which the main chain moiety is an Si—O bond and the side chain moiety that is bonded to the Si atom of the Si—O bond is a “group containing a phenolic hydroxyl group”.

In the constitutional unit (a1), the phenolic hydroxyl group forms a crosslinked structure by being subjected to the action of an acid generated from a component (B) described later upon exposure. As a result, the molecular weight of the component (A1) is increased. Further, since the constitutional unit (a1) contains the phenolic hydroxyl group, the component (A1) exhibits solubility in an alkali developing solution, and thus the alkali developability is imparted to the negative-tone resist composition.

Examples of the preferred constitutional unit (a1) include a constitutional unit represented by General Formula (a1-1).

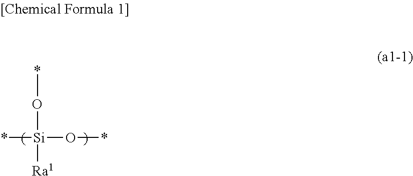

[In the formula, Ra¹ is a hydrocarbon group having a phenolic hydroxyl group. * represents a bonding site.]

Specific examples of the “hydrocarbon group having a phenolic hydroxyl group” as Ra¹ in Formula (a1-1) are shown below. In the chemical formulae, * indicates a bonding site.

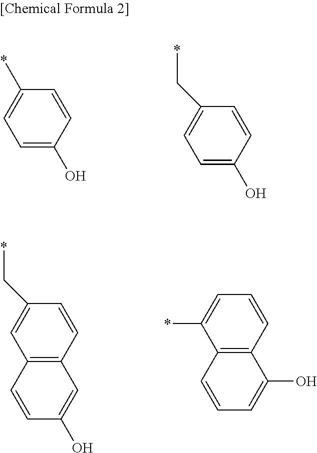 [SMILES: *c1ccc(O)cc1 ; *Cc1ccc(O)cc1 ; *Cc1ccc2cc(O)ccc2c1 ; *c1cccc2c(O)cccc12]

Preferred examples of the constitutional unit represented by General Formula (a1-1) include the constitutional unit represented by General Formula (a1-1-1).

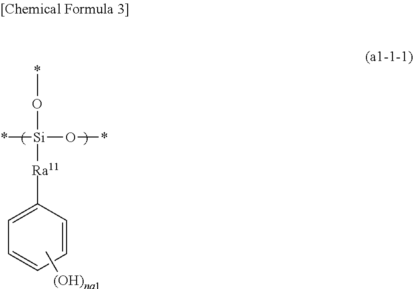

[In the formula, Ra¹¹ represents an alkylene group having 1 to 5 carbon atoms or a single bond. na1 represents an integer in a range of 1 to 3.]

In General Formula (a1-1-1), Ra¹¹ is preferably an alkylene group having 1 to 5 carbon atoms.

The alkylene group as Ra¹¹ may be linear, branched, or cyclic, and it is preferably linear or branched.

The alkylene group as Ra¹¹ has 1 to 5 carbon atoms and preferably has 1 to 3 carbon atoms. Examples of the alkylene group as Ra¹¹ include a methylene group, an ethylene group, a propylene group, a butylene group, a pentylene group, and an isopropylene group. Among these, a methylene group, an ethylene group, a propylene group, or an isopropylene group is preferable, a methylene group or an ethylene group is more preferable, and a methylene group is still more preferable.

In General Formula (a1-1-1), na1 represents an integer in a range of 1 to 3, preferably 1 or 2, and more preferably 1.

The bonding position of the hydroxyl group to the benzene ring may be any one of the o-position, the m-position, or the p-position, and for example, the p-position is industrially preferable.

The constitutional unit (a1) contained in the polysiloxane may be one kind or may be two or more kinds.

The proportion of the constitutional unit (a1) in the polysiloxane is preferably 40% by mole or more, more preferably 50% by mole or more, and still more preferably 60% by mole or more, and may be 100% by mole (a homopolymer), with respect to the total (100% by mole) of all constitutional units constituting the polysiloxane.

In a case where the proportion of the constitutional unit (a1) is equal to or larger than the lower limit value of the above-described preferred range, a resist pattern having good lithography characteristics is easily formed.

Other Constitutional Units

The polysiloxane having the constitutional unit (a1) may further have other constitutional units in addition to the constitutional unit (a1).

Examples of the other constitutional units include a constitutional unit (a2) containing an alkyl group, a constitutional unit (a3) represented by Chemical Formula (a3-1), and a constitutional unit (a4) represented by Chemical Formula (a4-1).

Constitutional Unit (a2)

The constitutional unit (a2) is a constitutional unit containing an alkyl group.

Examples of the constitutional unit (a2) include those in which the main chain moiety is an Si—O bond and the side chain moiety that is bonded to the Si atom of the Si—O bond is an alkyl group.

In a case where the constitutional unit (a2) is contained, it is possible to easily control the characteristics of a resist film that is formed by using the negative-tone resist composition.

Preferred examples of the constitutional unit (a2) include a constitutional unit represented by General Formula (a2-1) and a constitutional unit represented by General Formula (a2-2).

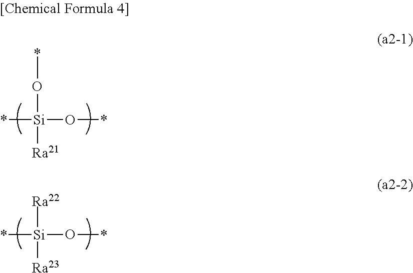

[In the formulae, Ra²¹, Ra²², and Ra²³ each independently represent an alkyl group having 1 to 10 carbon atoms.]

In General Formulae (a2-1) and (a2-2) described above, the alkyl group as Ra²¹, Ra²², and Ra²³ may be linear, branched, or cyclic, and it is preferably linear or branched.

The alkyl group as Ra²¹, Ra²², and Ra²³ has 1 to 10 carbon atoms, preferably 1 to 5 carbon atoms, and more preferably 1 to 3 carbon atoms.

Examples of the alkyl group as Ra²¹, Ra²², and Ra²³ include a methyl group, an ethyl group, a propyl group, a butyl group, a pentyl group, a hexyl group, an octyl group, a decyl group, an isopropyl group, an isobutyl group, a sec-butyl group, a tert-butyl group, and a 2-ethylhexyl group. Among these, a methyl group, an ethyl group, a propyl group, a butyl group, a pentyl group, an isopropyl group, an isobutyl group, a sec-butyl group, or a tert-butyl group is preferable, a methyl group, an ethyl group, a propyl group, or an isopropyl group is more preferable, a methyl group or an ethyl group is still more preferable, and a methyl group is particularly preferable.

The constitutional unit (a2) contained in the polysiloxane may be one kind or may be two or more kinds.

In a case where the polysiloxane further has a constitutional unit (a2) in addition to the constitutional unit (a1), the proportion of the constitutional unit (a2) in the polysiloxane is preferably in a range of 10% to 60% by mole, more preferably in a range of 10% to 55% by mole, and still more preferably in a range of 15% to 50% by mole, with respect to the total (100% by mole) of all constitutional units constituting the polysiloxane.

The proportion of the constitutional unit represented by General Formula (a2-1) is preferably in a range of 20% to 60% by mole, more preferably in a range of 25% to 55% by mole, and still more preferably in a range of 30% to 50% by mole, with respect to the total (100% by mole) of all constitutional units constituting the polysiloxane.

The proportion of the constitutional unit represented by General Formula (a2-2) is preferably in a range of 10% to 40% by mole, more preferably in a range of 10% to 30% by mole, and still more preferably in a range of 15% to 25% by mole, with respect to the total (100% by mole) of all constitutional units constituting the polysiloxane.

In a case where the proportion of the constitutional unit (a2) is equal to or larger than the lower limit value of the above-described preferred range, etching resistance is easily enhanced, whereas in a case of being equal to or smaller than the upper limit value of the above-described preferred range, a resist pattern having good lithography characteristics is easily formed.

Constitutional Unit (a3)

The constitutional unit (a3) is a constitutional unit represented by Chemical Formula (a3-1).

This constitutional unit (a3) is useful for enhancing the lithography characteristics. The introduction of the constitutional unit (a3) facilitates the control of the dissolution rate.

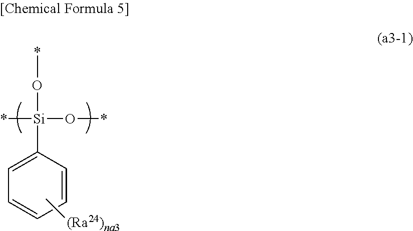

[In the formula, Ra²⁴ represents a hydrocarbon group having 1 to 6 carbon atoms. na3 represents an integer in a range of 0 to 5.]

In General Formula (a3-1), the hydrocarbon group as Ra²⁴ may be linear, branched, or cyclic, and it is preferably linear or branched. The hydrocarbon group as Ra²⁴ may be a saturated hydrocarbon group or may be an unsaturated hydrocarbon group, and it is preferably a saturated hydrocarbon group.

The hydrocarbon group as Ra²⁴ has 1 to 6 carbon atoms, preferably 1 to 5 carbon atoms, and more preferably 1 to 3 carbon atoms. The hydrocarbon group as Ra²⁴ is preferably an alkyl group, and examples thereof include a methyl group, an ethyl group, a propyl group, an isopropyl group, an n-butyl group, an isobutyl group, a tert-butyl group, a pentyl group, an isopentyl group, and a neopentyl group, among which a methyl group, an ethyl group, a propyl group, or an isopropyl group is preferable, a methyl group or an ethyl group is more preferable, and a methyl group is still more preferable.

In General Formula (a3-1), na3 represents an integer in a range of 0 to 5, preferably an integer in a range of 0 to 3, more preferably 0 or 1, and particularly preferably 0.

The constitutional unit (a3) contained in the polysiloxane may be one kind or may be two or more kinds.

In a case where the polysiloxane further has a constitutional unit (a3) in addition to the constitutional unit (a1), the proportion of the constitutional unit (a3) in the polysiloxane is preferably in a range of 30% by mole or less, more preferably in a range of 5% to 30% by mole, and particularly preferably in a range of 5% to 25% by mole, with respect to the total (100% by mole) of all constitutional units constituting the polysiloxane.

Constitutional Unit (a4)

The constitutional unit (a4) is a constitutional unit represented by Chemical Formula (a4-1).

This constitutional unit (a4) is useful for enhancing the lithography characteristics. The introduction of the constitutional unit (a4) facilitates the control of the dissolution rate.

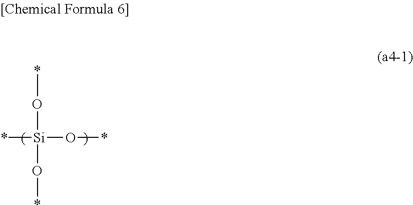

In a case where the polysiloxane further has a constitutional unit (a4) in addition to the constitutional unit (a1), the proportion of the constitutional unit (a4) in the polysiloxane is preferably in a range of 30% by mole or less, more preferably in a range of 5% to 30% by mole, and particularly preferably in a range of 10% to 25% by mole, with respect to the total (100% by mole) of all constitutional units constituting the polysiloxane.

In addition, the polysiloxane in the present embodiment may be a copolymer in which the polymer main chain consists of a repeating structure of an Si—O bond and which further contains, in addition to the constitutional unit (a1), at least one of an alkoxy group and a hydroxy group.

In the negative-tone resist composition according to the present embodiment, the component (A1) is preferably a polysiloxane in which the polymer main chain consists of a repeating structure of an Si—O bond and which has a repeating structure of the constitutional unit represented by General Formula (a1-1). Among these polysiloxanes, the preferred one is as follows: a silsesquioxane resin consisting of a repeating structure of a constitutional unit represented by General Formula (a1-1); a silsesquioxane resin having a repeating structure of a constitutional unit represented by General Formula (a1-1) and a constitutional unit represented by General Formula (a2-1); a silsesquioxane resin having a repeating structure of a constitutional unit represented by General Formula (a1-1) and a constitutional unit represented by General Formula (a2-2); a silsesquioxane resin having a repeating structure of a constitutional unit represented by General Formula (a1-1) and a constitutional unit represented by General Formula (a3-1); a silsesquioxane resin having a repeating structure of a constitutional unit represented by General Formula (a1-1), a constitutional unit represented by General Formula (a2-1), and a constitutional unit represented by General Formula (a3-1); a silsesquioxane resin having a repeating structure of a constitutional unit represented by General Formula (a1-1), a constitutional unit represented by General Formula (a2-2), and a constitutional unit represented by General Formula (a3-1); or a silsesquioxane resin having a repeating structure of a constitutional unit represented by General Formula (a1-1), a constitutional unit represented by General Formula (a3-1), and a constitutional unit represented by General Formula (a4-1).

The mass average molecular weight (Mw) (in terms of the polystyrene equivalent value determined by gel permeation chromatography (GPC)) of the component (A1) is not particularly limited, and it is, for example, 1,000 or more, preferably in a range of 1,000 to 10,000, more preferably in a range of 1,500 to 7,500, and still more preferably in a range of 2,000 to 5,000.

In a case where the Mw of the component (A1) is equal to or smaller than the upper limit value of the above-described preferred range, the solubility in an organic solvent is further improved. On the other hand, in a case where it is equal to or larger than the lower limit value of the above-described preferred range, the patterning properties of the resist film become better, and the lithography characteristics of the formed resist pattern are further improved.

<<Silicon-Containing Polymer (A2)>>

In the negative-tone resist composition according to the present embodiment, a silicon-containing resin (A2) (hereinafter, referred to as a “component (A2)”), which does not correspond to the component (A1), may be used in combination as the component (A).

The proportion of the component (A1) in the component (A) is preferably 25% by mass or more, more preferably 50% by mass or more, still more preferably 75% by mass or more, and may be 100% by mass with respect to the total mass of the component (A). In a case where the proportion is 25% by mass or more, a resist pattern having various excellent lithography characteristics such as high sensitivity and roughness amelioration and having excellent etching resistance can be easily formed.

The component (A) contained in the negative-tone resist composition according to the present embodiment may be one kind or may be two or more kinds.

The content of the component (A) in the negative-tone resist composition according to the present embodiment may be adjusted depending on the film thickness to be formed.

<Acid Generator Component (B)>

The acid generator component (B) (the component (B)) that is used in the negative-tone resist composition according to the present embodiment contains a sulfonium salt (B1) having a fluorine atom in the cation moiety (hereinafter, also referred to as a “component (B1)”).

Since the negative-tone resist composition according to the present embodiment contains the component (B1), the usability particularly for EUV is increased.

<<Sulfonium Salt (B1) Having Fluorine Atom in Cation Moiety>>

The component (B1) is not particularly limited as long as it is a sulfonium salt and has a fluorine atom in the cation moiety, and those which have been proposed so far as an acid generator for a chemical amplification-type resist composition in the related art can be used.

Preferred examples of such a component (B1) include a compound represented by General Formula (b1-1).

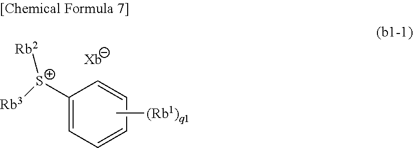

[In the formula, Rb¹ represents a fluorinated alkyl group or a fluorine atom. q1 is an integer in a range of 1 to 5. Rb² and Rb³ each independently represent a hydrocarbon group which may have a substituent. Rb² and Rb³ may be bonded to each other to form a ring together with a sulfur atom in the formula. Rb² or Rb³ may form a condensed ring together with a sulfur atom and a benzene ring in the formula. Xb⁻ represents a counter anion].

In Formula (b1-1), Rb¹ represents a fluorinated alkyl group or a fluorine atom. The fluorinated alkyl group as Rb¹ is preferably a linear or branched fluorinated alkyl group having 1 to 5 carbon atoms, more preferably a linear fluorinated alkyl group having 1 to 5 carbon atoms, and particularly preferably a trifluoromethyl group.

In Formula (b1-1), q1 represents an integer in a range of 1 to 5, preferably an integer in a range of 1 to 4, and more preferably an integer in a range of 2 to 4.

In Formula (b1-1), Rb¹ is preferably bonded to the ortho or meta position of the benzene ring, and it is more preferably bonded to the meta position of the benzene ring from the viewpoint of photolysis efficiency.

In Formula (b1-1), Rb² and Rb³ each independently represent a hydrocarbon group which may have a substituent.

Examples of the hydrocarbon group which may have a substituent, as Rb² and Rb³, include an aryl group which may have a substituent, an alkyl group which may have a substituent, and an alkenyl group which may have a substituent.

Examples of the aryl group as Rb² and Rb³ include an unsubstituted aryl group having 6 to 20 carbon atoms, where a phenyl group or a naphthyl group is preferable.

The alkyl group as Rb² and Rb³ is preferably a chain-like or cyclic alkyl group, where the alkyl group has 1 to 30 carbon atoms.

The alkenyl group as Rb² and Rb³ preferably has 2 to 10 carbon atoms.

Examples of the substituent which may be contained in the hydrocarbon group as Rb² and Rb³ include an alkyl group, a halogen atom, a halogenated alkyl group, a carbonyl group, a cyano group, an amino group, an aryl group, and a group represented by each of General Formulae (ca-r-1) to (ca-r-7).

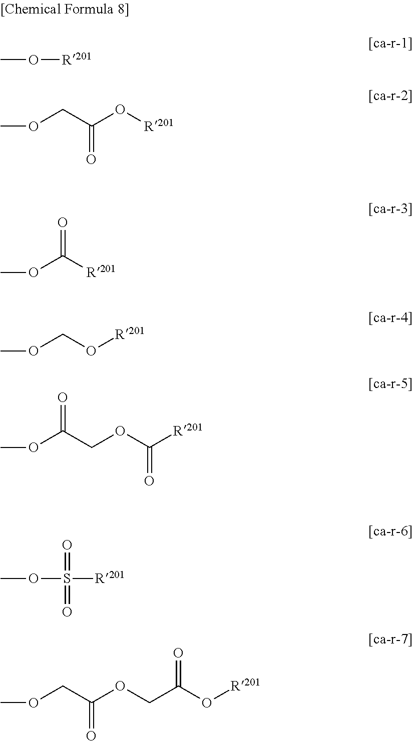

[In the formulae, each R′²⁰¹ independently represents a hydrogen atom, a cyclic group which may have a substituent, a chain-like alkyl group which may have a substituent, or a chain-like alkenyl group which may have a substituent.]

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R′²⁰¹ is a hydrocarbon group having an aromatic ring. The aromatic hydrocarbon group preferably has 3 to 30 carbon atoms, more preferably 5 to 30 carbon atoms, still more preferably 5 to 20 carbon atoms, particularly preferably 6 to 15 carbon atoms, and most preferably 6 to 10 carbon atoms. Here, the number of carbon atoms in a substituent is not included in the number of carbon atoms.

Specific examples of the aromatic ring contained in the aromatic hydrocarbon group as R′²⁰¹ include benzene, fluorene, naphthalene, anthracene, phenanthrene, biphenyl, or an aromatic heterocyclic ring obtained by substituting a part of carbon atoms constituting these aromatic rings with a hetero atom. Examples of the hetero atom in the aromatic heterocyclic rings include an oxygen atom, a sulfur atom, and a nitrogen atom.

Specific examples of the aromatic hydrocarbon group as R′²⁰¹ include a group obtained by removing one hydrogen atom from the above-described aromatic ring (an aryl group; for example, a phenyl group or a naphthyl group) and a group in which one hydrogen atom in the aromatic ring has been substituted with an alkylene group (for example, an arylalkyl group such as a benzyl group, a phenethyl group, a 1-naphthylmethyl group, a 2-naphthylmethyl group, 1-naphthylethyl group, or a 2-naphthylethyl group). The alkylene group (an alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group as R′²⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding the alicyclic hydrocarbon group to the terminal of a linear or branched aliphatic hydrocarbon group, and a group obtained by interposing the alicyclic hydrocarbon group is in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among them, the cyclic aliphatic hydrocarbon group as R′²⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear or branched aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and particularly preferably 1 to 3 carbon atoms.

The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R′²⁰¹ may contain a hetero atom such as a heterocyclic ring. Specific examples thereof include a lactone-containing cyclic groups, an —SO₂-containing cyclic group, and another heterocyclic group represented by each of Chemical Formulae (r-hr-1) to (r-hr-16) described below. In the chemical formulae, * indicates a bonding site.

The term “lactone-containing cyclic group” indicates a cyclic group that contains a ring (lactone ring) containing a —O—C(═O)— in the ring skeleton. In a case where the lactone ring is counted as the first ring and the group contains only the lactone ring, the group is referred to as a monocyclic group. Further, in a case where the group has other ring structures, the group is referred to as a polycyclic group regardless of the structures. The lactone-containing cyclic group may be a monocyclic group or a polycyclic group.

The term “—SO₂-containing cyclic group” indicates a cyclic group having a ring containing —SO₂— in the ring skeleton thereof. Specifically, the —SO₂-containing cyclic group is a cyclic group in which the sulfur atom (S) in —SO₂— forms a part of the ring skeleton of the cyclic group. In a case where a ring containing —SO₂— in the ring skeleton thereof is counted as the first ring and the group contains only the ring, the group is referred to as a monocyclic group. In a case where the group further has other ring structures, such a group is referred to as a polycyclic group regardless of the structures. The —SO₂-containing cyclic group may be a monocyclic group or a polycyclic group. Particularly, the —SO₂-containing cyclic group is preferably a cyclic group containing —O—SO₂— in the ring skeleton thereof, in other words, a cyclic group containing a sultone ring in which —O—S— in the —O—SO₂— group forms a part of the ring skeleton thereof.

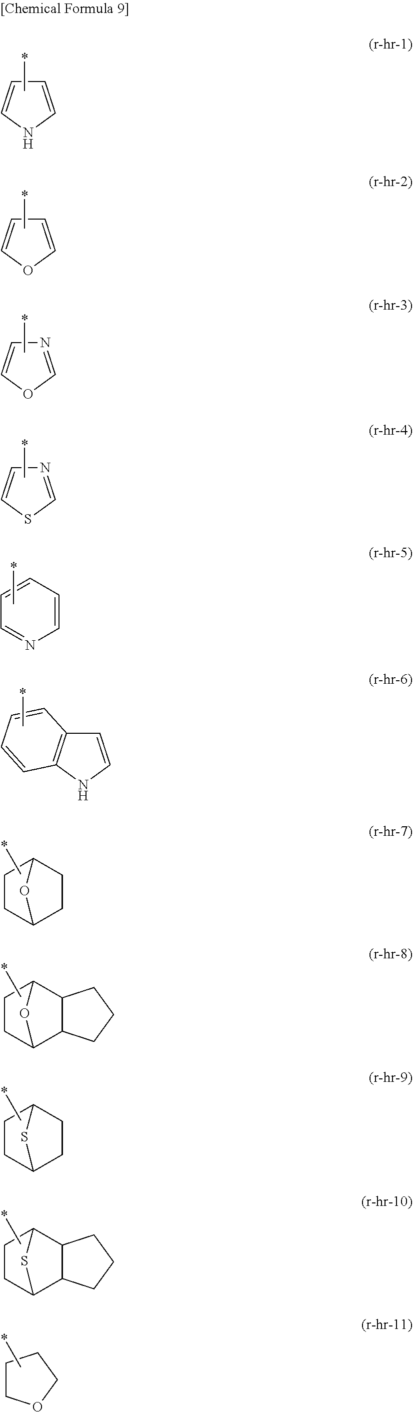

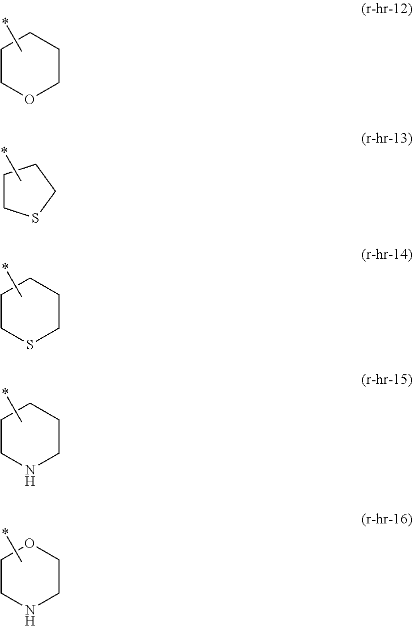

Examples of the substituent which may be contained in the cyclic group as R′²⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the above-described halogenated alkyl group as the substituent include a group in which part or all of hydrogen atoms in an alkyl group having 1 to 5 carbon atoms such as a methyl group, an ethyl group, a propyl group, an n-butyl group, or a tert-butyl group have been substituted with the above-described halogen atom.

The carbonyl group as the substituent is a group that is substituted for a methylene group (—CH₂—) constituting the cyclic hydrocarbon group.

Chain-Like Alkyl Group which May have Substituent:

The chain-like alkyl group as R′²⁰¹ may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecil group, an icosyl group, a henicosyl group, and a docosyl group.

The branched alkyl group preferably has 3 to 20 carbon atoms, more preferably 3 to 15 carbon atoms, and most preferably 3 to 10 carbon atoms. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

Such a chain-like alkenyl group as R′²⁰¹ may be linear or branched, preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent which may be contained in the chain-like alkyl group or alkenyl group as R′²⁰¹ include an alkoxy group, a halogen atom, a halogenated alkyl group, a hydroxyl group, a carbonyl group, a nitro group, an amino group, and a cyclic group as R′201

As the cyclic group which may have a substituent, the chain-like alkyl group which may have a substituent, or the chain-like alkenyl group which may have a substituent, as R′²⁰¹, a tertiary alkyl ester-type acid dissociable group can be also mentioned as the cyclic group which may have a substituent or the chain-like alkyl group which may have a substituent, in addition to the groups described above.

Among them, R′²⁰¹ is preferably a cyclic group which may have a substituent and more preferably a cyclic hydrocarbon group which may have a substituent. More specifically, a phenyl group, a naphthyl group, a group obtained by removing one or more hydrogen atoms from a polycycloalkane, a lactone-containing cyclic group, a —SO₂-containing cyclic group, or the like is preferable.

In General Formula (b1-1), Rb² and Rb³ may be bonded to each other to form a ring together with a sulfur atom in the formula. Alternatively, Rb² and Rb³ may form a condensed ring together with a sulfur atom and a benzene ring in the formula.

In a case where Rb² and Rb³ form a condensed ring together with a sulfur atom and a benzene ring in the formula, they may be bonded to each other via a hetero atom such as a sulfur atom, an oxygen atom, or a nitrogen atom, or a functional group such as a carbonyl group, —SO—, —SO₂—, —SO₃—, —COO—, —CONH—, or —N(R_{N})— (here, R_{N} represents an alkyl group having 1 to 5 carbon atoms).

Regarding the ring formed by Rb² and Rb³ together with a sulfur atom and a benzene ring in the formula, one ring containing the sulfur atom in the formula in the ring skeleton thereof is preferably, including the sulfur atom, a 3-membered to 10-membered ring and particularly preferably a 5-membered to 7-membered ring. Specific examples of the ring to be formed include a thiophene ring, a thiazole ring, a benzothiophene ring, a thianthrene ring, a dibenzothiophene ring, a 9H-thioxanthene ring, a thioxanthone ring, a thianthrene ring, a phenoxathiin ring, a tetrahydrothiophenium ring, and a tetrahydrothiopyranium ring.

In General Formula (b1-1), it is preferable that Rb² and Rb³ are a phenyl group or a naphthyl group, or Rb² and Rb³ are bonded to each other to form a ring or a condensed ring together with a sulfur atom in the formula.

Specific examples of the cation moiety in the compound represented by General Formula (b1-1) are shown below.

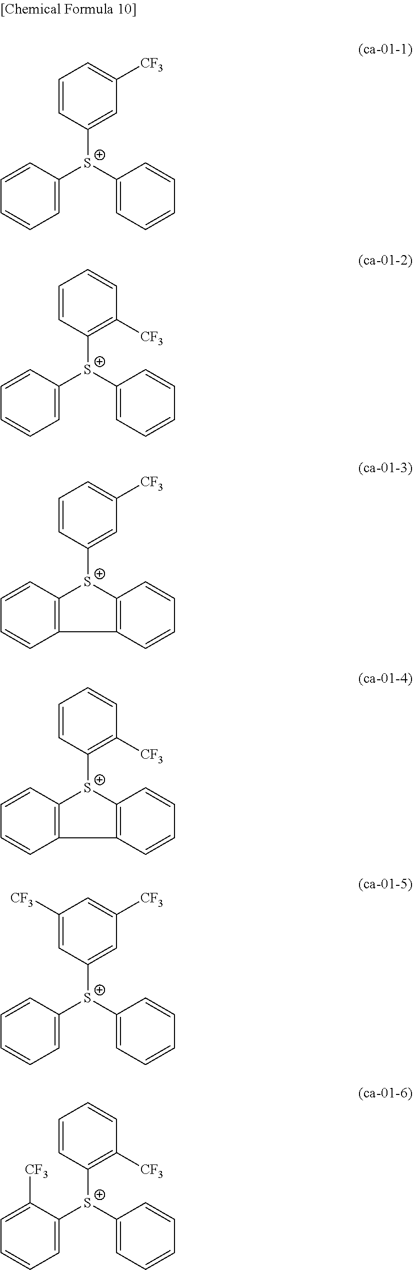

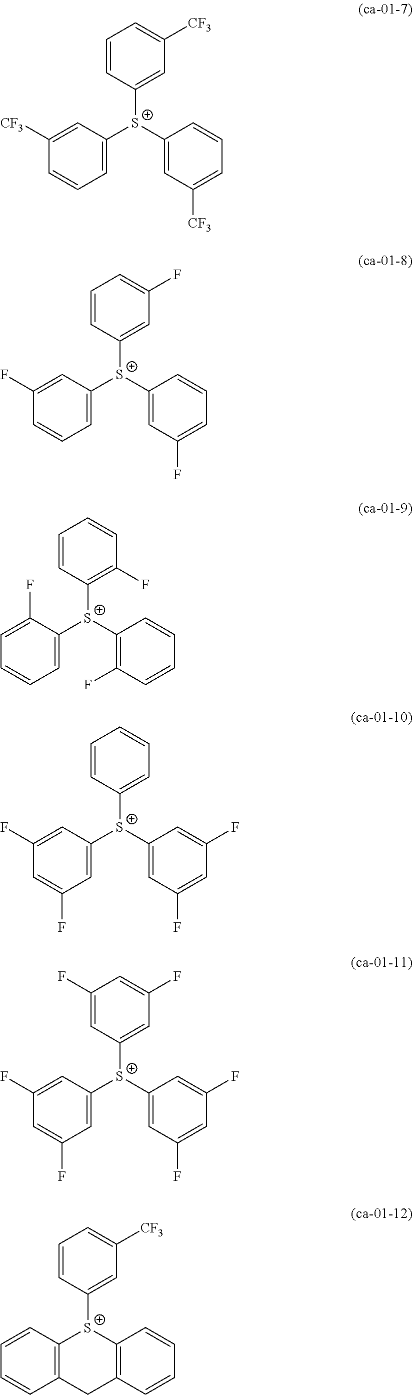

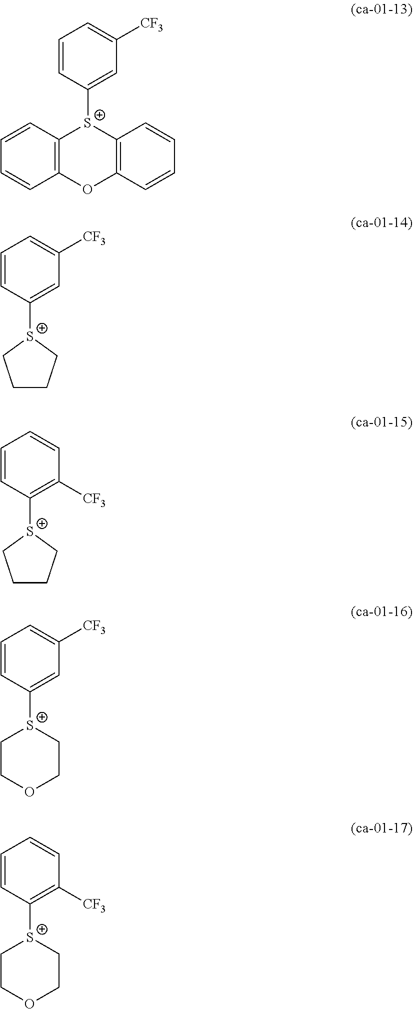

In Formula (b1-1), Xb⁻ represents a counter anion.

Xb⁻ is not particularly limited, and an anion known as the anion moiety of an acid generator component for a resist composition can be appropriately used.

Examples of Xb⁻ include an anion represented by General Formula (b0-1-an1), an anion represented by General Formula (b0-1-an2), or an anion represented by General Formula (b0-1-an3).

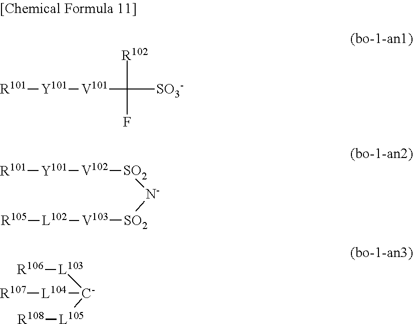

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring structure. R¹⁰² represents a fluorinated alkyl group having 1 to 5 carbon atoms or a fluorine atom. Y¹⁰¹ represents a divalent linking group containing an oxygen atom or a single bond. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO—, or —SO₂—.]

Anion Represented by General Formula (b0-1-an1)

In General Formula (b0-1-an1), R¹⁰¹ represents a cyclic group which may have a substituent, a chain-like alkyl group which may have a substituent, or a chain-like alkenyl group which may have a substituent.

Cyclic Group which May have Substituent:

The cyclic group is preferably a cyclic hydrocarbon group, and the cyclic hydrocarbon group may be an aromatic hydrocarbon group or an aliphatic hydrocarbon group. The aliphatic hydrocarbon group indicates a hydrocarbon group that has no aromaticity. The aliphatic hydrocarbon group may be saturated or unsaturated. In general, it is preferable that the aliphatic hydrocarbon group is saturated.

The aromatic hydrocarbon group as R¹⁰¹ is a hydrocarbon group having an aromatic ring. The aromatic hydrocarbon group preferably has 3 to 30 carbon atoms, more preferably 5 to 30, still more preferably 5 to 20, and particularly preferably 6 to 18. However, the number of carbon atoms in a substituent is not included in the number of carbon atoms.

Specific examples of the aromatic ring contained in the aromatic hydrocarbon group as R¹⁰¹ include benzene, fluorene, naphthalene, anthracene, phenanthrene, biphenyl, and an aromatic heterocyclic ring obtained by substituting part of carbon atoms constituting one of these aromatic rings with a hetero atom. Examples of the hetero atom in the aromatic heterocyclic rings include an oxygen atom, a sulfur atom, and a nitrogen atom.

Specific examples of the aromatic hydrocarbon group as R¹⁰¹ include a group (an aryl group: for example, a phenyl group or a naphthyl group) obtained by removing one hydrogen atom from the above aromatic ring; a group (for example, an arylalkyl group such as a benzyl group, a phenethyl group, a 1-naphthylmethyl group, a 2-naphthylmethyl group, 1-naphthylethyl group, or a 2-naphthylethyl group) obtained by substituting one hydrogen atom of the above aromatic ring with an alkylene group; and a group obtained by removing one hydrogen atom from a condensed ring in which the above aromatic ring is condensed with a crosslinked aliphatic ring such as bicycloheptane or bicyclooctane. The alkylene group (an alkyl chain in the arylalkyl group) preferably has 1 to 4 carbon atoms, more preferably 1 or 2 carbon atoms, and particularly preferably 1 carbon atom.

Examples of the cyclic aliphatic hydrocarbon group as R¹⁰¹ include aliphatic hydrocarbon groups containing a ring in the structure thereof.

Examples of the aliphatic hydrocarbon group containing a ring in the structure thereof include an alicyclic hydrocarbon group (a group obtained by removing one hydrogen atom from an aliphatic hydrocarbon ring), a group obtained by bonding the alicyclic hydrocarbon group to the terminal of a linear or branched aliphatic hydrocarbon group, and a group obtained by interposing the alicyclic hydrocarbon group is in a linear or branched aliphatic hydrocarbon group.

The alicyclic hydrocarbon group preferably has 3 to 20 carbon atoms and more preferably 3 to 12 carbon atoms.

The alicyclic hydrocarbon group may be a polycyclic group or a monocyclic group. The monocyclic alicyclic hydrocarbon group is preferably a group obtained by removing one or more hydrogen atoms from a monocycloalkane. The monocycloalkane preferably has 3 to 6 carbon atoms, and specific examples thereof include cyclopentane and cyclohexane. The polycyclic alicyclic hydrocarbon group is preferably a group obtained by removing one or more hydrogen atoms from a polycycloalkane, and the polycycloalkane preferably has 7 to 30 carbon atoms. Among the above, the polycycloalkane is more preferably a polycycloalkane having a bridged ring-based polycyclic skeleton, such as adamantane, norbornane, isobornane, tricyclodecane, or tetracyclododecane; or a polycycloalkane having a condensed ring-based polycyclic skeleton, such as a cyclic group having a steroid skeleton.

Among them, the cyclic aliphatic hydrocarbon group as R¹⁰¹ is preferably a group obtained by removing one or more hydrogen atoms from a monocycloalkane or a polycycloalkane, more preferably a group obtained by removing one hydrogen atom from a polycycloalkane, particularly preferably an adamantyl group or a norbornyl group, and most preferably an adamantyl group.

The linear aliphatic hydrocarbon group which may be bonded to the alicyclic hydrocarbon group preferably has 1 to 10 carbon atoms, more preferably 1 to 6 carbon atoms, still more preferably 1 to 4 carbon atoms, and most preferably 1 to 3 carbon atoms. The linear aliphatic hydrocarbon group is preferably a linear alkylene group, and specific examples thereof include a methylene group [—CH₂—], an ethylene group [—(CH₂)₂—], a trimethylene group [—(CH₂)₃—], a tetramethylene group [—(CH₂)₄—], and a pentamethylene group [—(CH₂)₅—].

The branched aliphatic hydrocarbon group which may be bonded to the alicyclic hydrocarbon group preferably has 2 to 10 carbon atoms, more preferably 3 to 6 carbon atoms, still more preferably 3 or 4 carbon atoms, and most preferably 3 carbon atoms. The branched aliphatic hydrocarbon group is preferably a branched alkylene group, and specific examples thereof include alkylalkylene groups, for example, alkylmethylene groups such as —CH(CH₃)—, —CH(CH₂CH₃)—, —C(CH₃)₂—, —C(CH₃)(CH₂CH₃)—, —C(CH₃)(CH₂CH₂CH₃)—, and —C(CH₂CH₃)₂—; alkylethylene groups such as —CH(CH₃)CH₂—, —CH(CH₃)CH(CH₃)—, —C(CH₃)₂CH₂—, —CH(CH₂CH₃)CH₂—, and —C(CH₂CH₃)₂—CH₂—; alkyltrimethylene groups such as —CH(CH₃)CH₂CH₂—, and —CH₂CH(CH₃)CH₂—; and alkyltetramethylene groups such as —CH(CH₃)CH₂CH₂CH₂—, and —CH₂CH(CH₃)CH₂CH₂—. The alkyl group in the alkylalkylene group is preferably a linear alkyl group having 1 to 5 carbon atoms.

The cyclic hydrocarbon group as R¹⁰¹ may contain a hetero atom such as a heterocyclic ring. Specific examples thereof include a lactone-containing cyclic groups, an —SO₂-containing cyclic group, and another heterocyclic group represented by each of Chemical Formulae (r-hr-1) to (r-hr-16) described above.

Examples of the substituent which may be contained in the cyclic group as R¹⁰¹ include an alkyl group, an alkoxy group, a halogen atom, a halogenated alkyl group, a hydroxyl group, a carbonyl group, and a nitro group.

The alkyl group as the substituent is preferably an alkyl group having 1 to 5 carbon atoms, and a methyl group, an ethyl group, a propyl group, an n-butyl group, or a tert-butyl group is most preferable.

The alkoxy group as the substituent is preferably an alkoxy group having 1 to 5 carbon atoms, more preferably a methoxy group, an ethoxy group, an n-propoxy group, an iso-propoxy group, an n-butoxy group, or a tert-butoxy group, and most preferably a methoxy group or an ethoxy group.

Examples of the halogen atom for the substituent include a fluorine atom, a chlorine atom, a bromine atom, and an iodine atom, and a fluorine atom is preferable.

Examples of the above-described halogenated alkyl group as the substituent include a group in which part or all of hydrogen atoms in an alkyl group having 1 to 5 carbon atoms such as a methyl group, an ethyl group, a propyl group, an n-butyl group, or a tert-butyl group have been substituted with the above-described halogen atom.

The carbonyl group as the substituent is a group that is substituted for a methylene group (—CH₂—) constituting the cyclic hydrocarbon group.

The cyclic hydrocarbon group as R¹⁰¹ may be a condensed cyclic group containing a condensed ring in which an aliphatic hydrocarbon ring is condensed with an aromatic ring. Examples of the condensed ring include a condensed ring in which one or more aromatic rings are condensed with a polycycloalkane having a bridged ring-based polycyclic skeleton. Specific examples of the bridged ring-based polycycloalkane include bicycloalkanes such as bicyclo[2.2.1]heptane (norbornane) and bicyclo[2.2.2]octane. The condensed ring type group is preferably a group containing a condensed ring, in which two or three aromatic rings are condensed with a bicycloalkane, and more preferably a group containing a condensed ring, in which two or three aromatic rings are condensed with bicyclo[2.2.2]octane.

Specific examples of the condensed cyclic group as R¹⁰¹ include those represented by General Formulae (r-br-1) to (r-br-2).

In the formulae, * represents a bonding site to which Y¹ in General Formula (b0-1-an1) is bonded.

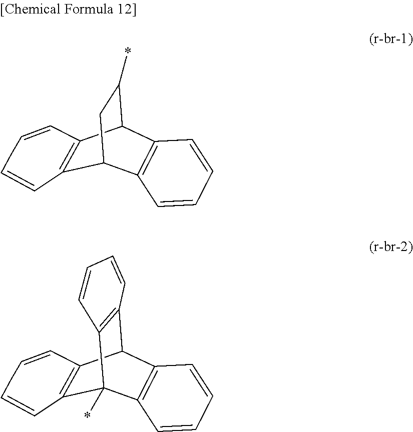

Examples of the substituent which may be contained in the condensed cyclic group as R¹⁰¹ include an alkyl group, an alkoxy group, a halogen atom, a halogenated alkyl group, a hydroxyl group, a carbonyl group, a nitro group, an aromatic hydrocarbon group, and an alicyclic hydrocarbon group.

Examples of the alkyl group, the alkoxy group, the halogen atom, and the halogenated alkyl group, as the substituent of the condensed cyclic group, include the same ones as those described as the substituent of the cyclic group as R¹⁰¹.

Examples of the aromatic hydrocarbon group as the substituent of the condensed cyclic group include a group obtained by removing one hydrogen atom from the above-described aromatic ring (an aryl group; for example, a phenyl group or a naphthyl group), a group obtained by substituting one hydrogen atom in the aromatic ring with an alkylene group (for example, an arylalkyl group such as a benzyl group, a phenethyl group, a 1-naphthylmethyl group, a 2-naphthylmethyl group, 1-naphthylethyl group, or a 2-naphthylethyl group), and a heterocyclic group represented by each of General Formulae (r-hr-1) to (r-hr-6).

Examples of the alicyclic hydrocarbon group as the substituent of the condensed cyclic group include a group obtained by removing one hydrogen atom from a monocycloalkane such as cyclopentane or cyclohexane; a group obtained by removing one or more hydrogen atoms from a polycycloalkane such as adamantane, norbornane, isobornane, tricyclodecane, or tetracyclododecane; a lactone-containing cyclic group; an —SO₂-containing cyclic group; and a heterocyclic group represented by each of General Formulae (r-hr-7) to (r-hr-16).

Chain-Like Alkyl Group which May have Substituent:

The chain-like alkyl group as R¹⁰¹ may be linear or branched.

The linear alkyl group preferably has 1 to 20 carbon atoms, more preferably 1 to 15 carbon atoms, and most preferably 1 to 10 carbon atoms. Specific examples thereof include a methyl group, an ethyl group, a propyl group, a butyl group, a pentyl group, a hexyl group, a heptyl group, an octyl group, a nonyl group, a decanyl group, an undecyl group, a dodecyl group, a tridecyl group, an isotridecyl group, a tetradecyl group, a pentadecyl group, a hexadecyl group, an isohexadecyl group, a heptadecyl group, an octadecyl group, a nonadecil group, an icosyl group, a henicosyl group, and a docosyl group.

The branched alkyl group preferably has 3 to 20 carbon atoms, more preferably 3 to 15, and most preferably 3 to 10. Specific examples thereof include a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, and a 4-methylpentyl group.

Chain-Like Alkenyl Group which May have Substituent:

A chain-like alkenyl group as R¹⁰¹ may be linear or branched, and the chain-like alkenyl group preferably has 2 to 10 carbon atoms, more preferably 2 to 5 carbon atoms, still more preferably 2 to 4 carbon atoms, and particularly preferably 3 carbon atoms. Examples of the linear alkenyl group include a vinyl group, a propenyl group (an allyl group), and a butynyl group. Examples of the branched alkenyl group include a 1-methylvinyl group, a 2-methylvinyl group, a 1-methylpropenyl group, and a 2-methylpropenyl group.

Among the above, the chain-like alkenyl group is preferably a linear alkenyl group, more preferably a vinyl group or a propenyl group, and particularly preferably a vinyl group.

Examples of the substituent which may be contained in the chain-like alkyl group or alkenyl group as R¹⁰¹ include an alkoxy group, a halogen atom, a halogenated alkyl group, a hydroxyl group, a carbonyl group, a nitro group, an amino group, and a cyclic group as R¹⁰¹.

Among the above, R¹⁰¹ is preferably a cyclic group which may have a substituent and more preferably a cyclic hydrocarbon group which may have a substituent. More specifically, it is preferably a group obtained by removing one or more hydrogen atoms from a phenyl group, a naphthyl group, or a polycycloalkane; a lactone-containing cyclic group; —SO₂-containing cyclic group; or the like.

In General Formula (b0-1-an1), Y¹⁰¹ represents a single bond or a divalent linking group containing an oxygen atom.

In a case where Y¹⁰¹ represents a divalent linking group containing an oxygen atom, Y¹⁰¹ may contain an atom other than the oxygen atom. Examples of the atom other than the oxygen atom include a carbon atom, a hydrogen atom, a sulfur atom, and a nitrogen atom.

Examples of divalent linking groups containing an oxygen atom include non-hydrocarbon-based oxygen atom-containing linking groups such as an oxygen atom (an ether bond; —O—), an ester bond (—C(═O)—O—), an oxycarbonyl group (—O—C(═O)—), an amide bond (—C(═O)—NH—), a carbonyl group (—C(═O)—), or a carbonate bond (—O—C(═O)—O—); and a combination of the above-described non-hydrocarbon-based oxygen atom-containing linking groups with an alkylene group. Furthermore, a sulfonyl group (—SO₂—) may be linked to the combination.

Examples of such a divalent linking group containing an oxygen atom include a linking group represented by each of General Formulae (y-a1-1) to (y-a1-7) shown below.

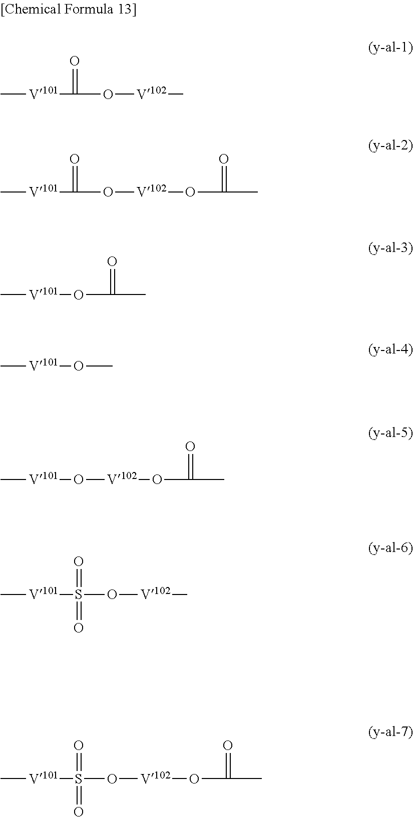

[In the formulae, V′¹⁰¹ represents a single bond or an alkylene group having 1 to 5 carbon atoms, and V′¹⁰² represents a divalent saturated hydrocarbon group having 1 to 30 carbon atoms.]

The divalent saturated hydrocarbon group as V′¹⁰² is preferably an alkylene group having 1 to 30 carbon atoms, more preferably an alkylene group having 1 to 10 carbon atoms, and still more preferably an alkylene group having 1 to 5 carbon atoms.

The alkylene group as V′¹⁰¹ and V′¹⁰² may be a linear alkylene group or a branched alkylene group, and a linear alkylene group is preferable.

Specific examples of the alkylene group as V′¹⁰¹ and V′¹⁰² include a methylene group [—CH₂—]; an alkylmethylene group such as —CH(CH₃)—, —CH(CH₂CH₃)—, —C(CH₃)₂—, —C(CH₃)(CH₂CH₃)—, —C(CH₃)(CH₂CH₂CH₃)—, or —C(CH₂CH₃)₂—; an ethylene group [—CH₂CH₂—]; an alkylethylene group such as —CH(CH₃)CH₂—, —CH(CH₃)CH(CH₃)—, —C(CH₃)₂CH₂—, or —CH(CH₂CH₃)CH₂—; a trimethylene group (n-propylene group) [—CH₂CH₂CH₂—]; an alkyltrimethylene group such as —CH(CH₃)CH₂CH₂— or —CH₂CH(CH₃)CH₂—; a tetramethylene group [—CH₂CH₂CH₂CH₂—]; an alkyltetramethylene group such as —CH(CH₃)CH₂CH₂CH₂— or —CH₂CH(CH₃)CH₂CH₂—; and a pentamethylene group [—CH₂CH₂CH₂CH₂CH₂—].

Further, part of methylene groups in the alkylene group as V′¹⁰¹ and V′¹⁰² may be substituted with a divalent aliphatic cyclic group having 5 to 10 carbon atoms.

The aliphatic cyclic group is preferably a divalent group in which one hydrogen atom has been removed from the cyclic aliphatic hydrocarbon group (a monocyclic aliphatic hydrocarbon group or a polycyclic aliphatic hydrocarbon group) and is more preferably a cyclohexylene group, a 1,5-adamantylene group, or a 2,6-adamantylene group.

Y¹⁰¹ preferably represents a divalent linking group containing an ester bond or a divalent linking group containing an ether bond and more preferably a linking group represented by each of General Formulae (y-a1-1) to (y-a1-5).

In General Formula (b0-1-an1), V¹⁰¹ represents a single bond, an alkylene group, or a fluorinated alkylene group. The alkylene group and the fluorinated alkylene group as V¹⁰¹ preferably have 1 to 4 carbon atoms. Examples of the fluorinated alkylene group as V¹⁰¹ include a group obtained by substituting part or all of hydrogen atoms in the alkylene group as V¹⁰¹ with a fluorine atom. Among them, V¹⁰¹ is preferably a linear fluorinated alkylene group having 1 to 4 carbon atoms or a single bond.

In General Formula (b0-1-an1), R¹⁰² represents a fluorine atom or a fluorinated alkyl group having 1 to 5 carbon atoms. R¹⁰² is preferably a fluorine atom or a perfluoroalkyl group having 1 to 5 carbon atoms and more preferably a fluorine atom.

In a case where Y¹⁰¹ represents a single bond, specific examples of the anion moiety represented by General Formula (b0-1-an1) include a fluorinated alkylsulfonate anion such as a trifluoromethanesulfonate anion or a perfluorobutanesulfonate anion; and in a case where Y¹⁰¹ represents a divalent linking group containing an oxygen atom, specific examples thereof include an anion represented by any one of General Formulae (an-1) to (an-3) shown below.

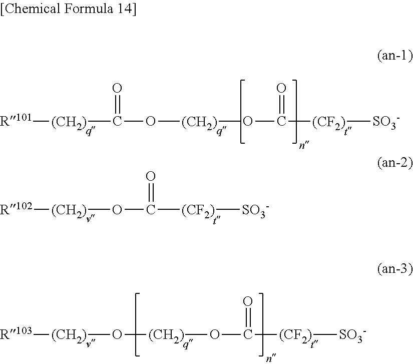

[In the formula, R″¹⁰¹ represents an aliphatic cyclic group which may have a substituent, a group represented by each of General Formulae (r-hr-1) to (r-hr-6), or a chain-like alkyl group which may have a substituent; R″¹⁰² represents an aliphatic cyclic group which may have a substituent, a lactone-containing cyclic group, or a —SO₂-containing cyclic group; R″¹⁰³ represents an aromatic cyclic group which may have a substituent, an aliphatic cyclic group which may have a substituent, or a chain-like alkenyl group which may have a substituent; and each v″ independently represents an integer in a range of 0 to 3, each q″ independently represents an integer in a range of 1 to 20, t″ represents an integer in a range of 1 to 3, and n″ represents 0 or 1.]

The aliphatic cyclic group as R″¹⁰¹, R″¹⁰², and R″¹⁰³ which may have a substituent is preferably the groups exemplified as the cyclic aliphatic hydrocarbon group as R¹⁰¹. Examples of the substituent include the same one as the substituent which may be substituted for a cyclic aliphatic hydrocarbon group as R¹⁰¹.

The aromatic cyclic group which may have a substituent, as R″¹⁰³, is preferably the group exemplified as the aromatic hydrocarbon group for the cyclic hydrocarbon group, as R¹⁰¹. Examples of the substituent include the same one as the substituent which may be substituted for the aromatic hydrocarbon group as R¹⁰¹.

The chain-like alkyl group as R″¹⁰¹, which may have a substituent, is preferably the groups exemplified as the chain-like alkyl groups as R¹⁰¹.

The chain-like alkenyl group as R″¹⁰³, which may have a substituent, is preferably the groups exemplified as the chain-like alkenyl groups as R¹⁰¹.

Anion Represented by General Formula (b0-1-an2)

In General Formula (b0-1-an2), R¹⁰⁴ and R¹⁰⁵ each independently represent a cyclic group which may have a substituent, a chain-like alkyl group which may have a substituent, or a chain-like alkenyl group which may have a substituent, and examples thereof each include the same one as R¹⁰¹ in General Formula (b0-1-an1). However, R¹⁰⁴ and R¹⁰⁵ may be bonded to each other to form a ring.

R¹⁰⁴ and R¹⁰⁵ are preferably a chain-like alkyl group which may have a substituent and more preferably a linear or branched alkyl group or a linear or branched fluorinated alkyl group.

The chain-like alkyl group preferably has 1 to 10 carbon atoms, more preferably 1 to 7 carbon atoms, and still more preferably 1 to 3 carbon atoms. It is preferable that the number of carbon atoms in the chain-like alkyl group as R¹⁰⁴ and R¹⁰⁵ is small since the solubility in a resist solvent is also excellent in this range of the number of carbon atoms. In addition, in the chain-like alkyl group R¹⁰⁴ and R¹⁰⁵, the larger the number of hydrogen atoms substituted with a fluorine atom, the stronger the acid strength, which is preferable. The proportion of fluorine atoms in the chain-like alkyl group, that is, the fluorination rate is preferably in a range of 70% to 100% and more preferably in a range of 90% to 100%, and it is most preferable that the chain-like alkyl group is a perfluoroalkyl group obtained substituting all hydrogen atoms with a fluorine atom.

in General Formula (b0-1-an2), V¹⁰² and V¹⁰³ each independently represent a single bond, an alkylene group, or a fluorinated alkylene group, and examples thereof each include the same one as V¹⁰¹ in General Formula (b0-1-an1).

In General Formula (b0-1-an2), L¹⁰¹ and L¹⁰² each independently represent a single bond or an oxygen atom.

Anion Represented by General Formula (b0-1-an3)

In General Formula (b0-1-an3), R¹⁰⁶ to R¹⁰⁸ each independently represent a cyclic group which may have a substituent, a chain-like alkyl group which may have a substituent, or a chain-like alkenyl group which may have a substituent, and examples thereof each include the same one as R¹⁰¹ in General Formula (b0-1-an1).

In General Formula (b0-1-an3), L¹⁰³ to L¹⁰⁵ each independently represent a single bond, —CO—, or —SO₂—.

In addition, in General Formula (b1-1), Xb⁻ may be R¹⁰⁹—SO₃⁻. Here, R¹⁰⁹ represents a cyclic group which may have a substituent, a chain-like alkyl group which may have a substituent, or a chain-like alkenyl group which may have a substituent, and examples thereof each include the same one as R¹⁰¹ in General Formula (b0-1-an1). However, the carbon atom adjacent to the S atom in R¹⁰⁹ has a fluorine atom bonded thereto.

In addition, in General Formula (b1-1), Xb⁻ may be a halogen anion. Here, examples of the halogen anion include a fluoride ion, a chloride ion, a bromide ion, and an iodide ion.

Among the above examples, as the anion moiety of the component (B1), an anion represented by General Formula (b0-1-an1) is preferable. Among the above, an anion represented by any one of General Formulae (an-1) to (an-3) is more preferable.

In the negative-tone resist composition according to the present embodiment, the component (B1) may be used alone or in a combination of two or more kinds thereof.

In the negative-tone resist composition according to the present embodiment, the content of the component (B1) is preferably 10 parts by mass or more, more preferably 10 to 50 parts by mass, still more preferably 10 to 40 parts by mass, and particularly preferably 15 to 30 parts by mass, with respect to 100 parts by mass of the component (A).

The proportion of the above-described component (B1) in the total component (B) contained in the negative-tone resist composition according to the present embodiment is, for example, 50% by mass or more, preferably 70% by mass or more, and more preferably 95% by mass or more. Here, it may be 100% by mass.

In a case where the content of the component (B1) is equal to or larger than the lower limit value of the above-described preferred range, the lithography characteristics such as sensitivity, a linewise roughness (LWR) reduction property, and a shape are further improved in the resist pattern formation. On the other hand, in a case where the content thereof is equal to or smaller than the upper limit value of the above-described preferred range, a homogeneous solution is easily obtained in a case where each of the components of the negative-tone resist composition is dissolved in an organic solvent, and the storage stability as a resist composition is further improved.

<<Component (B2)>>

The negative-tone resist composition according to the present embodiment may contain an acid generator component (hereinafter, also referred to as a “component (B2)”) other than the component (B1) described above as long as the effects of the present invention are not impaired.

The component (B2) is not particularly limited, and those which have been proposed so far as an acid generator for a chemical amplification-type resist composition in the related art can be used.

Examples of these acid generators are numerous and include onium salt-based acid generators such as iodonium salts and sulfonium salts; oxime sulfonate-based acid generators; diazomethane-based acid generators such as bisalkyl or bisaryl sulfonyl diazomethanes and poly(bis-sulfonyl)diazomethanes; nitrobenzyl sulfonate-based acid generators; iminosulfonate-based acid generators; and disulfonate-based acid generators.

Examples of the onium salt-based acid generator include a compound represented by General Formula (b-1) (hereinafter, also referred to as a “component (b-1)”), a compound represented by General Formula (b-2) (hereinafter, also referred to as a “component (b-2)”), and a compound represented by General Formula (b-3) (hereinafter, also referred to as a “component (b-3)”).

It is noted that the component (b-1), the component (b-2), and the component (b-3) do not include compounds corresponding to the component (B1) described above.

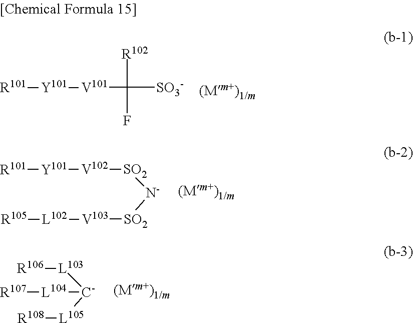

[In the formulae, R¹⁰¹ and R¹⁰⁴ to R¹⁰⁸ each independently represent a cyclic group which may have a substituent, a chain-like alkyl group which may have a substituent, or a chain-like alkenyl group which may have a substituent. R¹⁰⁴ and R¹⁰⁵ may be bonded to each other to form a ring. R¹⁰² represents a fluorine atom or a fluorinated alkyl group having 1 to 5 carbon atoms. Y¹⁰¹ represents a single bond or a divalent linking group containing an oxygen atom. V¹⁰¹ to V¹⁰³ each independently represent a single bond, an alkylene group, or a fluorinated alkylene group. L¹⁰¹ and L¹⁰² each independently represent a single bond or an oxygen atom. L¹⁰³ to L¹⁰⁵ each independently represent a single bond, —CO— or —SO₂—. m represents an integer of 1 or more, and M′^{m+} represents an m-valent onium cation.]

In General Formulae (b-1), (b-2), and (b-3), R¹⁰¹ and R¹⁰⁴ to R¹⁰⁸ are the same as R¹⁰¹ and R¹⁰⁴ to R¹⁰⁸ in General Formulae (b0-1-an1) to (b0-1-an3).

In Formula (b-2), R¹⁰⁴ and R¹⁰⁵ are the same as R¹⁰⁴ and R¹⁰⁵ in Formula (b0-1-an2).

In Formula (b-1), Y¹⁰¹ is the same as Y¹⁰¹ in Formula (b0-1-an1).

In General Formulae (b-1) and (b-2), V¹⁰¹ to V¹⁰³ are the same as V¹⁰¹ to V¹⁰³ in General Formulae (b0-1-an1) and (b0-1-an2).

In Formula (b-2), L¹⁰¹ to L¹⁰² are the same as L¹⁰¹ to L¹⁰² in Formula (b0-1-an2).

In Formula (b-3), L¹⁰³ to L¹⁰⁵ are the same as L¹⁰³ to L¹⁰⁵ in Formula (b0-1-an3).

In General Formulae (b-1), (b-2), and (b-3), m represents an integer of 1 or more. M′^{m+} represents an m-valent onium cation and suitable examples thereof include a sulfonium cation and an iodonium cation.

Preferred examples of the cation moiety ((M′^{m+})_{l/m}) include an organic cation represented by each of General Formulae (ca-1) to (ca-3). However, those that are the same as the cation moiety in the compound represented by General Formula (b1-1) are excluded.

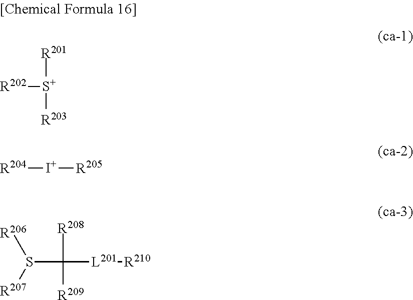

[In the formulae, R²⁰¹ to R²⁰⁷ each independently represent an aryl group, an alkyl group, or an alkenyl group, each of which may have a substituent. R²⁰¹ to R²⁰³ and R²⁰⁶ and R²⁰⁷ may be bonded to each other to form a ring together with the sulfur atoms in the formulae. R²⁰⁸ and R²⁰⁹ each independently represent a hydrogen atom or an alkyl group having 1 to 5 carbon atoms. R²¹⁰ represents an aryl group which may have a substituent, an alkyl group which may have a substituent, an alkenyl group which may have a substituent, or an —SO₂-containing cyclic group which may have a substituent. L²⁰¹ represents —C(═O)— or —C(═O)—O—.]

The aryl group as R²⁰¹ to R²⁰⁷ is the same as the aryl group as Rb² and Rb³ in General Formula (b1-1).

The alkyl group as R²⁰¹ to R²⁰⁷ is the same as the alkyl group as Rb² and Rb³ in General Formula (b1-1).

The alkenyl group as R²⁰¹ to R²⁰⁷ preferably has 2 to 10 carbon atoms.

Examples of the substituent which may be contained in R²⁰¹ to R²⁰⁷ and R²¹⁰ include an alkyl group, a halogen atom (excluding a fluorine atom), a halogenated alkyl group (excluding a fluorinated alkyl group), a carbonyl group, a cyano group, an amino group, an aryl group, and a group represented by each of General Formulae (ca-r-1) to (ca-r-7) described above.

The description for a ring formed in a case where R²⁰¹ to R²⁰³ and R²⁰⁶ and R²⁰⁷ are bonded to each other to form the ring together with a sulfur atom in the formula is the same as the description in a case where R^{b2} and R^{b3} are bonded to each other to form a ring together with a sulfur atom in General Formula (b1-1).

R²⁰⁸ and R²⁰⁹ each independently represent a hydrogen atom or an alkyl group having 1 to 5 carbon atoms and are preferably a hydrogen atom or an alkyl group having 1 to 3 carbon atoms. In a case where R²⁰⁸ and R²⁰⁹ each independently represent an alkyl group, R²⁰⁸ and R²⁰⁹ may be bonded to each other to form a ring.

R²¹⁰ represents an aryl group which may have a substituent, an alkyl group which may have a substituent, an alkenyl group which may have a substituent, or an —SO₂-containing cyclic group which may have a substituent.

Examples of the aryl group as R²¹⁰ include an unsubstituted aryl group having 6 to 20 carbon atoms, and a phenyl group or a naphthyl group is preferable.

The alkyl group as R²¹⁰, a chain-like or cyclic alkyl group having 1 to 30 carbon atoms is preferable.

The alkenyl group as R²¹⁰ preferably has 2 to 10 carbon atoms.

The —SO₂-containing cyclic group which may have a substituent, as R²¹⁰, is preferably a “—SO₂-containing polycyclic group”.

Specific examples of the suitable cation represented by General Formula (ca-1) include a cation represented by each of Chemical Formulae (ca-1-1) to (ca-1-63) shown below.

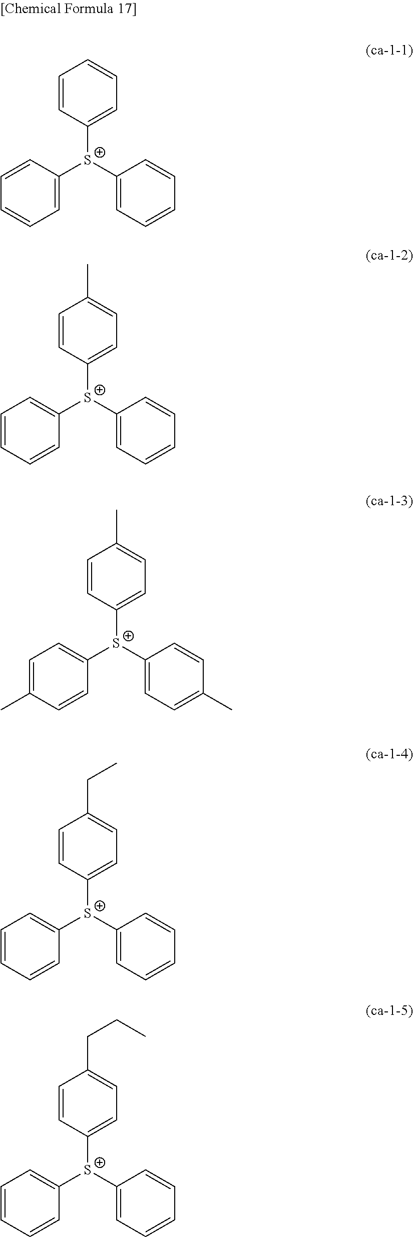

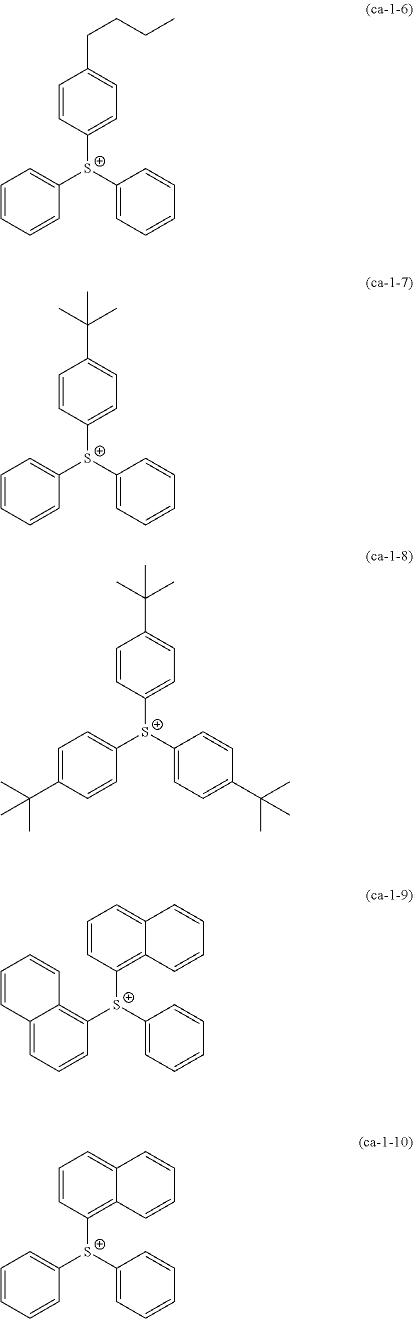

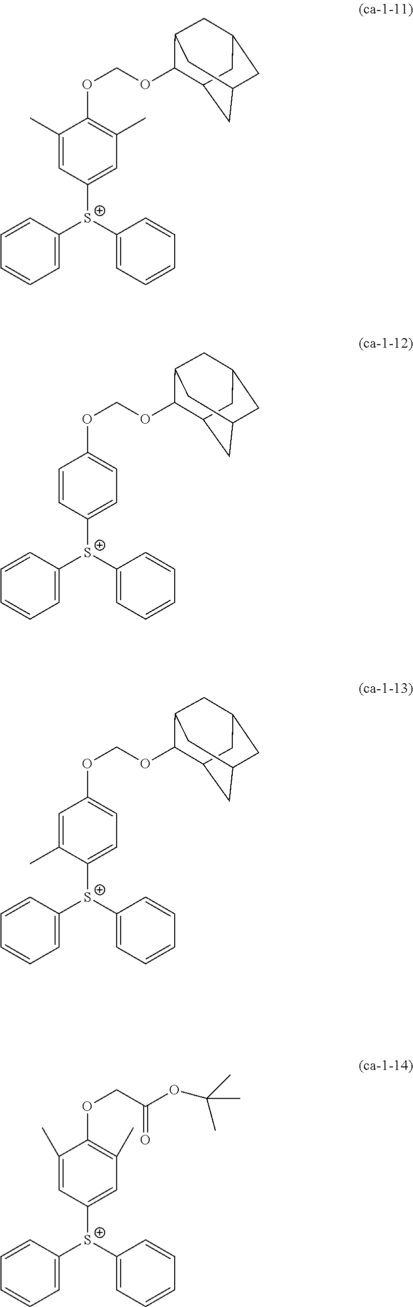

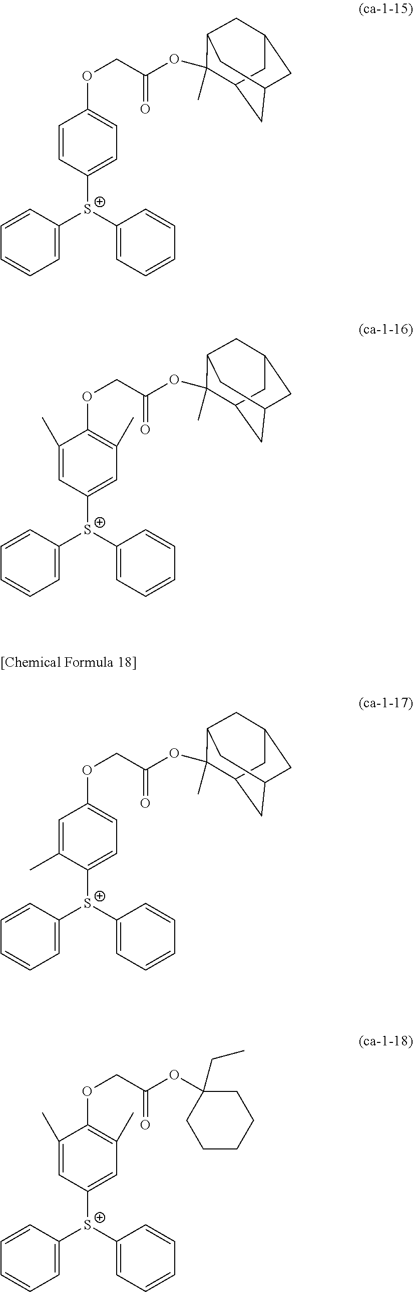

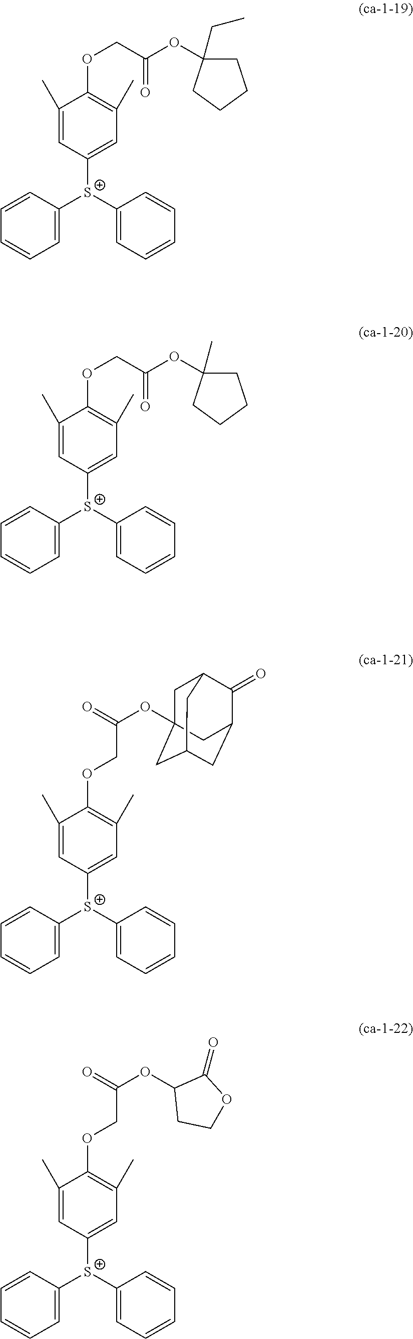

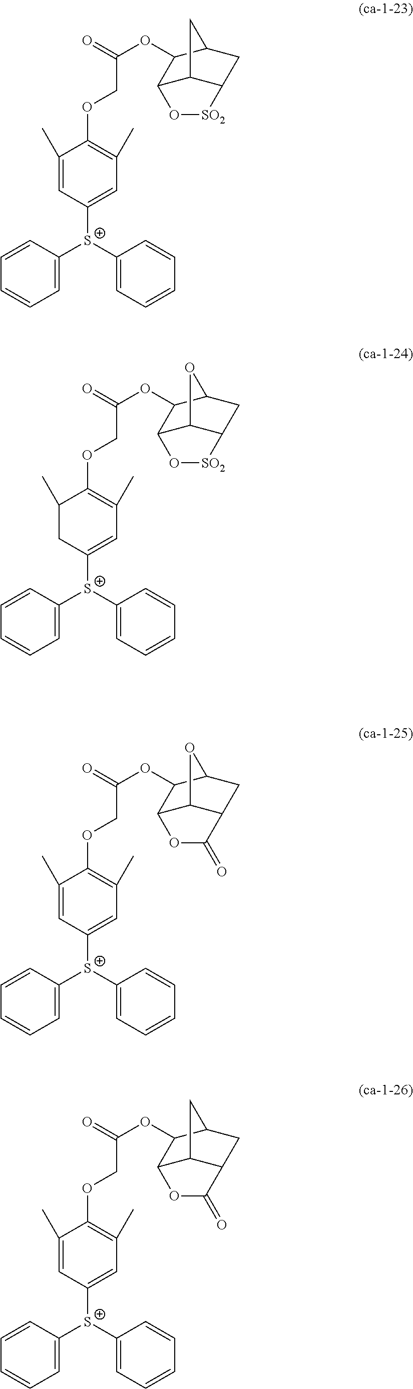

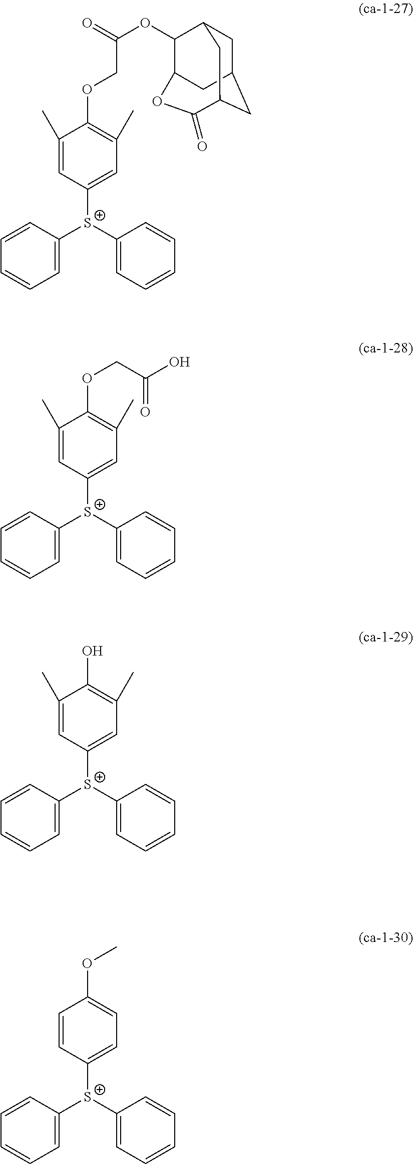

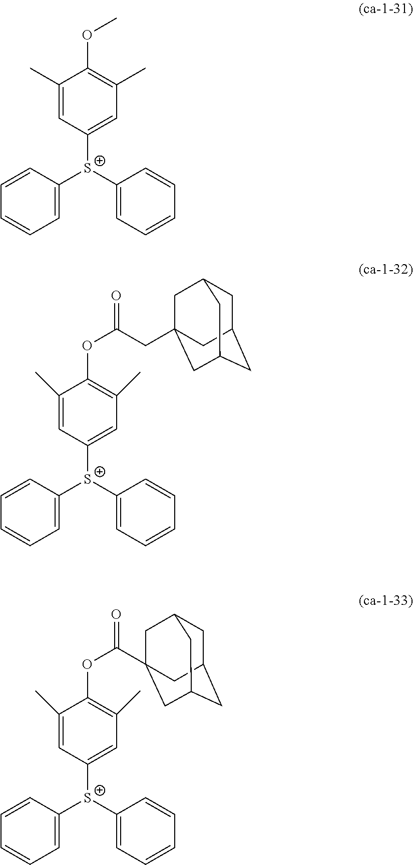

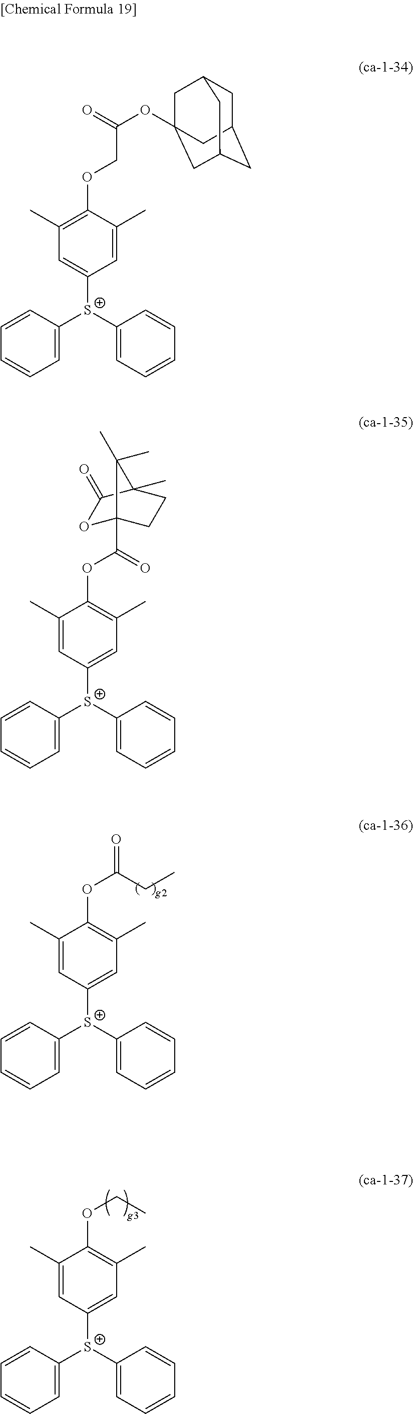

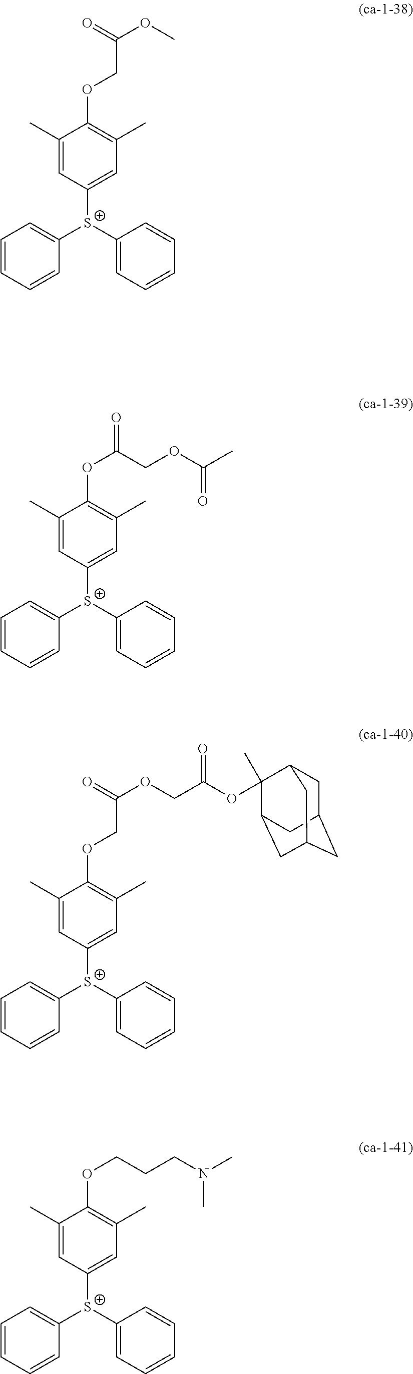

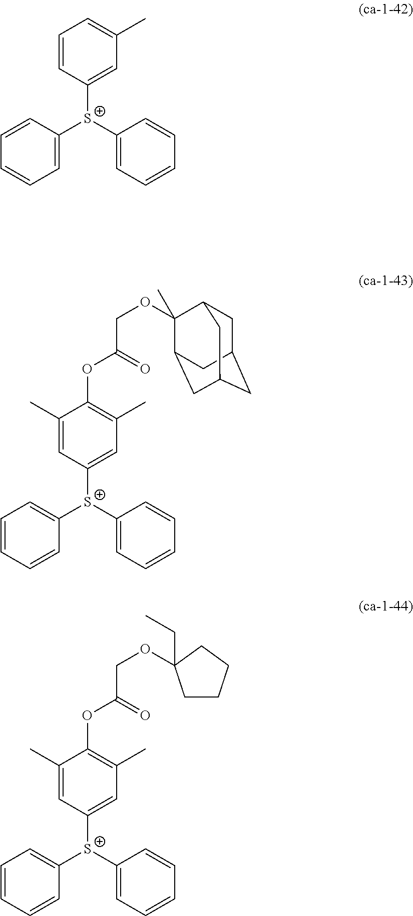

[In the formulae, g2 and g3 indicate the numbers of repetitions, g2 represents an integer in a range of 0 to 20, and g3 represents an integer in a range of 0 to 20.]

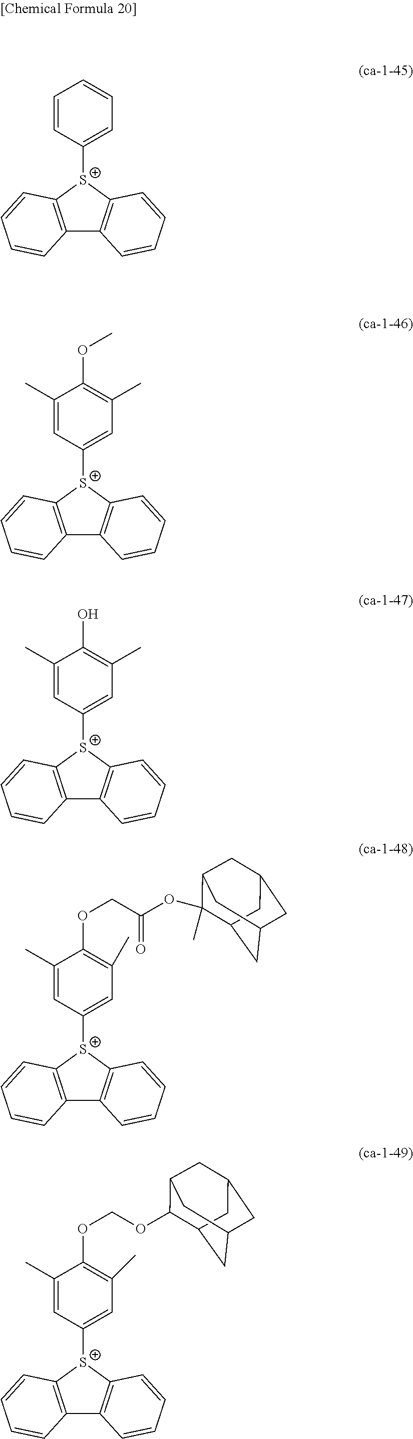 [SMILES: c1ccc(-[s+]2c3ccccc3c3ccccc32)cc1 ; COc1c(C)cc(-[s+]2c3ccccc3c3ccccc32)cc1C ; Cc1cc(-[s+]2c3ccccc3c3ccccc32)cc(C)c1O ; Cc1cc(-[s+]2c3ccccc3c3ccccc32)cc(C)c1OCC(=O)OC1(C)C2CC3CC(C2)CC1C3 ; Cc1cc(-[s+]2c3ccccc3c3ccccc32)cc(C)c1OCOC1C2CC3CC(C2)CC1C3]

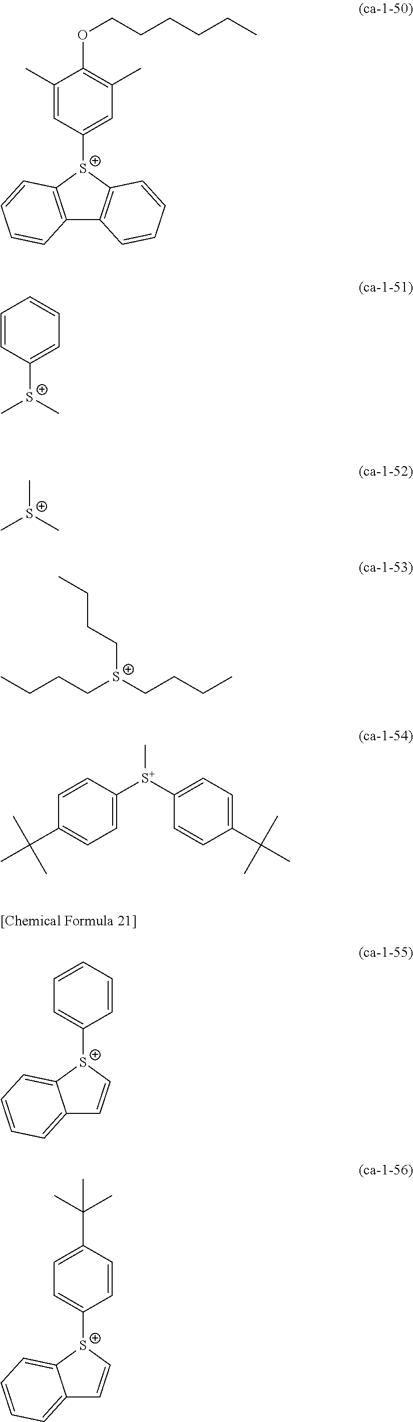

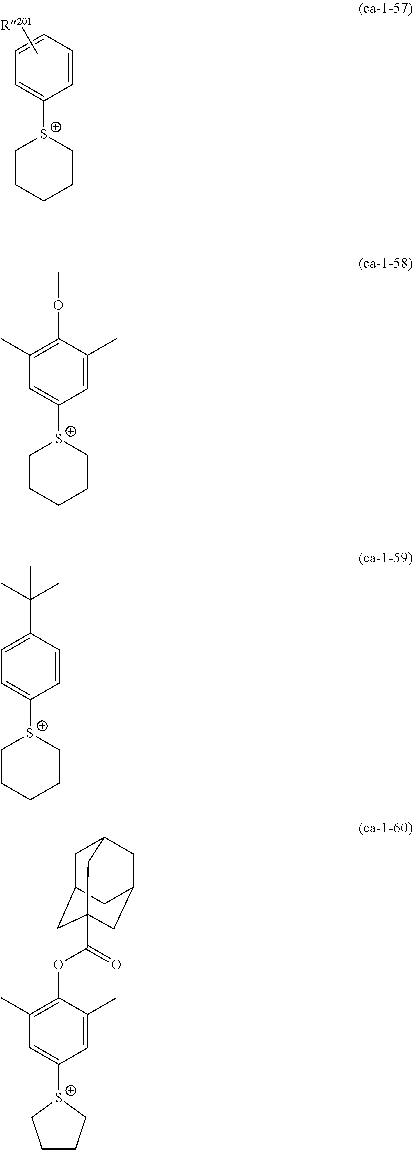

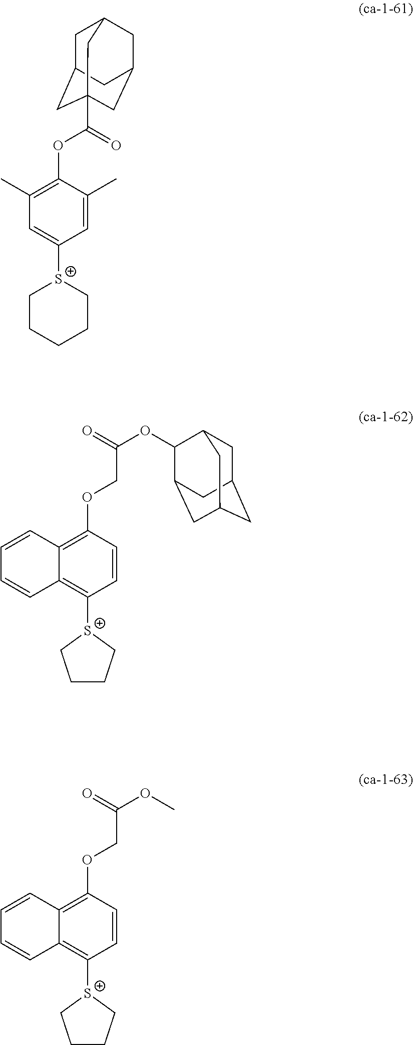 [SMILES: Cc1cc([S+]2CCCCC2)cc(C)c1OC(=O)C12CC3CC(CC(C3)C1)C2 ; O=C(COc1ccc([S+]2CCCC2)c2ccccc12)OC1C2CC3CC(C2)CC1C3 ; COC(=O)COc1ccc([S+]2CCCC2)c2ccccc12]

[In the formula, R″²⁰¹ represents a hydrogen atom or a substituent, and examples of the substituent include the same ones as those exemplified as the substituent which may be contained in R²⁰¹ to R²⁰⁷ and R²¹⁰.]

Specific examples of suitable cations represented by General Formula (ca-2) include a diphenyliodonium cation and a bis(4-tert-butylphenyl)iodonium cation.

Specific examples of the suitable cation represented by General Formula (ca-3) include a cation represented by each of General Formulae (ca-3-1) to (ca-3-6) shown below.

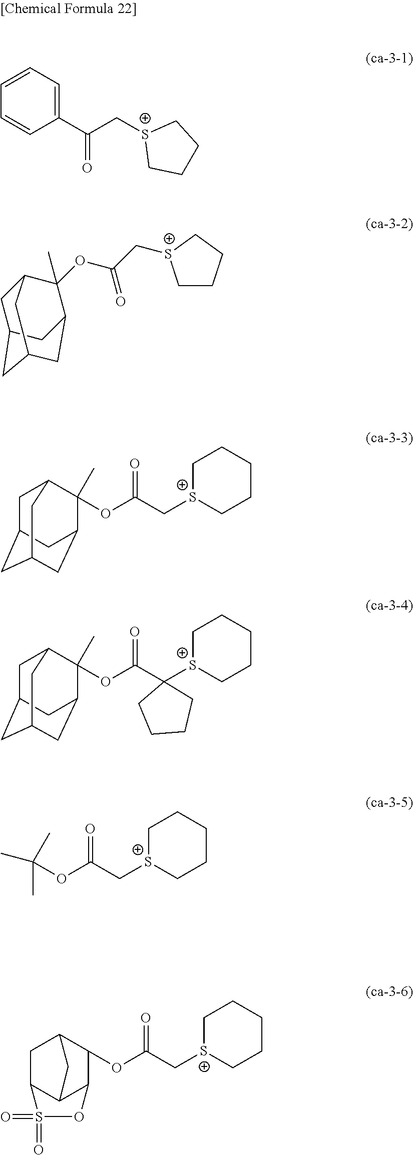

Among the above, the cation moiety (M′^{m+})_{l/m} is preferably a cation represented by General Formula (ca-1), and more preferably a cation represented by each of General Formulae (ca-1-1) to (ca-1-63).

In the negative-tone resist composition according to the present embodiment, the component (B2) may be used alone or in a combination of two or more kinds thereof.

In a case where the negative-tone resist composition contains the component (B2), the content of the component (B2) in the negative-tone resist composition is preferably 25 parts by mass or less, more preferably in a range of 1 to 20 parts by mass, and still more preferably in a range of 5 to 10 parts by mass with respect to 100 parts by mass of the component (A).

In a case where the content of the component (B2) is set to be in the above-described range, pattern formation can be satisfactorily carried out.

<Crosslinking Agent Component (C)>

Examples of the crosslinking agent component (C) (the component (C)) that is used in the negative-tone resist composition according to the present embodiment include a melamine-based crosslinking agent, a urea-based crosslinking agent, an alkylene urea-based crosslinking agent, a glycoluril-based crosslinking agent, a phenol-based crosslinking agent, and an epoxy-based crosslinking agent.

It is noted that the term “lower” used below means having 1 to 5 carbon atoms.

Examples of the melamine-based crosslinking agent include a compound obtained by reacting melamine with formaldehyde to substitute a hydrogen atom of an amino group with a hydroxymethyl group; and a compound obtained by reacting melamine, formaldehyde, and a lower alcohol to substitute a hydrogen atom of an amino group with a lower alkoxymethyl group. Specific examples thereof include hexamethoxymethyl melamine, hexaethoxymethyl melamine, hexapropoxymethyl melamine, and hexabutoxybutyl melamine, among which hexamethoxymethyl melamine is preferable.

Examples of the urea-based crosslinking agent include a compound obtained by reacting urea with formaldehyde to substitute a hydrogen atom of an amino group with a hydroxymethyl group; and a compound obtained by reacting urea, formaldehyde, and a lower alcohol to substitute a hydrogen atom of an amino group with a lower alkoxymethyl group. Specific examples thereof include bismethoxymethyl urea, bisethoxymethyl urea, bispropoxymethyl urea, and bisbutoxymethyl urea, among which bismethoxymethyl urea is preferable.

Examples of the alkylene urea-based crosslinking agent include a compound represented by General Formula (CA-1).

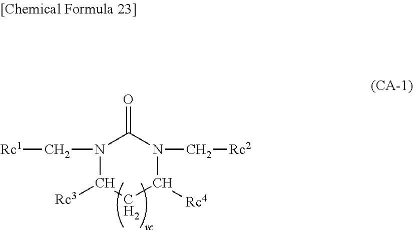

[In Formula (CA-1), Rc¹ and Rc² each independently represent a hydroxyl group or a lower alkoxy group. Rc³ and Rc⁴ each independently represent a hydrogen atom, a hydroxyl group, or a lower alkoxy group. vc represents an integer in a range of 0 to 2.]

In a case of being a lower alkoxy group, Rc¹ and Rc² are preferably an alkoxy group having 1 to 4 carbon atoms and may be linear or branched. Rc¹ and Rc² may be the same or different from each other, where they are more preferably the same.

In a case of being a lower alkoxy group, Rc³ and Rc⁴ are preferably an alkoxy group having 1 to 4 carbon atoms and may be linear or branched. Rc³ and Rc⁴ may be the same or different from each other, where they are more preferably the same.

vc represents an integer in a range of 0 to 2 and is preferably 0 or 1.

In particular, the alkylene urea-based crosslinking agent is preferably a compound in which vc is 0 (an ethylene urea-based crosslinking agent) and/or a compound in which vc is 1 (a propylene urea-based crosslinking agent).

The compound represented by General Formula (CA-1) can be obtained by subjecting an alkylene urea to a condensation reaction with formalin or by subjecting the product of this reaction to a reaction with a lower alcohol.

Specific examples of the alkylene urea-based crosslinking agent include ethylene urea-based crosslinking agents such as mono- and/or dihydroxymethylated ethylene urea, mono- and/or dimethoxymethylated ethylene urea, mono- and/or diethoxymethylated ethylene urea, mono- and/or dipropoxyethylated ethylene urea, and mono- and/or dibutoxymethylated ethylene urea; propylene urea-based crosslinking agents such as mono- and/or dihydroxymethylated propylene urea, mono- and/or dimethoxymethylated propylene urea, mono- and/or diethoxymethylated propylene urea, mono- and/or dipropoxymethylated propylene urea, and mono- and/or dibutoxymethylated propylene urea; 1,3-di(methoxymethyl) 4,5-dihydroxy-2-imidazolidinone; and 1,3-di(methoxymethyl)-4,5-dimethoxy-2-imidazolidinone.

Examples of the glycoluril-based crosslinking agent include a glycoluril derivative having a substitution with one or both of a hydroxyalkyl group and an alkoxyalkyl group having 1 to 4 carbon atoms at the N-position. Such a glycoluril derivative can be obtained by subjecting glycoluril to a condensation reaction with formalin or by subjecting the product of this reaction to a reaction with a lower alcohol.

Specific examples of the glycoluril-based crosslinking agents include mono-, di-, tri-, tri-, and/or tetrahydroxymethylated glycoluril; mono-, di-, tri-, tri-, and/or tetramethoxymethylated glycoluril; mono-, di-, tri-, tri-, and/or tetraethoxymethylated glycoluril; mono-, di-, tri-, tri-, and/or tetrapropoxymethylated glycoluril; and mono-, di-, tri-, tri-, and/or tetrabutoxymethylated glycoluril.

The phenol-based crosslinking agent is not particularly limited as long as it is a compound having a plurality of phenolic core structures in the same molecule, and any phenol-based crosslinking agent can be selected and used. In a case where a plurality of phenolic core structures is contained, crosslinking reactivity is improved.

The number of phenolic core structures is preferably 2 to 5, more preferably 2 to 4, and still more preferably 2 or 3.

Suitable phenol-based crosslinking agents are shown below.

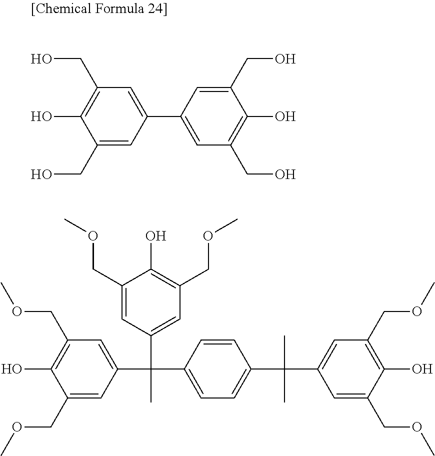

The epoxy-based crosslinking agent is not particularly limited as long as it has an epoxy group, and any epoxy-based crosslinking agent can be selected and used. Among the above, the one having two or more epoxy groups is preferable. In a case where two or more epoxy groups are contained, crosslinking reactivity is improved.

The number of epoxy groups is preferably 2 or more, more preferably 2 to 4, and most preferably 2.

Suitable epoxy-based crosslinking agents are shown below.

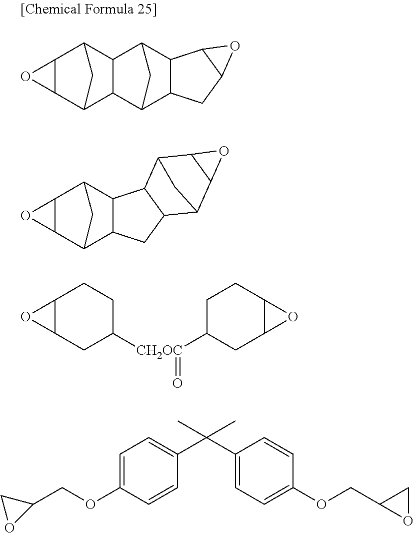

Among them, the component (C) is preferably a compound having an alkylol group such as a methylol group or an alkoxyalkyl group such as a methoxymethyl group, and more preferably a crosslinking agent selected from the group consisting of a glycoluril-based crosslinking agent and a phenol-based crosslinking agent. Suitable examples of such a crosslinking agent include a compound represented by General Formula (c1-1).

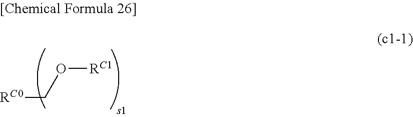

[In the formula, s1 represents an integer in a range of 1 to 10. R^{C0} is a glycoluril structure or a multicore phenol structure. R^{C1} represents an alkyl group having 1 to 5 carbon atoms or a hydrogen atom.]

In Formula (c1-1), s1 represents an integer in a range of 1 to 10, preferably an integer in a range of 2 to 10, and more preferably an integer in a range of 4 to 9.

In Formula (c1-1), the glycoluril structure in R^{C0} refers to a structure represented by Chemical Formula (R^{C0}-1).

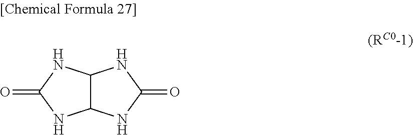

In Formula (c1-1), the multicore phenol structure in R^{C0} refers to a structure containing two or more selected from the group consisting of a phenol structure and a naphthol structure.

In the negative-tone resist composition according to the present embodiment, the component (C) may be used alone or in a combination of two or more kinds thereof.

In the negative-tone resist composition according to the present embodiment, the content of the component (C) is preferably in a range of 1 to 50 parts by mass, more preferably in a range of 3 to 40 parts by mass, still more preferably in a range of 5 to 30 parts by mass, and most preferably in a range of 5 to 25 parts by mass, with respect to 100 parts by mass of the component (A).

In a case where the content of the component (C) is equal to or larger than the lower limit value of the above-described preferred range, the crosslinking proceeds sufficiently to facilitate obtaining a dissolution contrast, and thus resolution performance and lithography characteristics are further improved. Further, a good resist pattern with less swelling can be obtained. In addition, in a case where the content thereof is equal to or smaller than the upper limit value of the above-described preferred range, the storage stability of the resist composition is good, and the temporal deterioration of the sensitivity is easily suppressed.

<Other Components>

The negative-tone resist composition according to the present embodiment may further contain other components in addition to the component (A), the component (B), and the component (C) described above. Examples of the other components include a component (D), a component (E), a component (F), and a component (S), which are described below.

<<Base Component>>

In addition to the above-described component (A), component (B), and component (C), the negative-tone resist composition according to the present embodiment preferably further contains a base component (D) (hereinafter, also referred to as a “component (D)”) which controls the diffusion of the acid generated from the component (B) upon exposure.

Such a component (D) acts as a quencher (an acid diffusion controlling agent) that traps acid that is generated in the negative-tone resist composition upon exposure.

Examples of the component (D) include a photodecomposable base (D1) having an acid diffusion controllability (hereinafter, referred to as a “component (D1)”) which is lost by the decomposition upon exposure and a nitrogen-containing organic compound (D2) (hereinafter, referred to as a “component (D2)”) which does not correspond to the component (D1). Among these, the photodecomposable base (the component (D1)) is preferable since it is easy to enhance the roughness reducing property. In addition, in a case where the component (D1) is contained, it becomes easy to enhance both the characteristics of increasing the sensitivity and suppressing the occurrence of coating defects.

In Regard to Component (D1)

In a case where a negative-tone resist composition containing the component (D1) is obtained, the contrast between exposed portions and unexposed portions of the resist film can be further improved at the time of the formation of a resist pattern.

The component (D1) is not particularly limited as long as it is decomposed upon exposure and loses the acid diffusion controllability. The component (D1) is preferably one or more compounds selected from the group consisting of a compound represented by General Formula (d1-1) (hereinafter, referred to as a “component (d1-1)”), a compound represented by General Formula (d1-2) (hereinafter, referred to as a “component (d1-2)”), and a compound represented by General Formula (d1-3) (hereinafter, referred to as a “component (d1-3)”).

At exposed portions of the resist film, the components (d1-1) to (d1-3) are decomposed and then lose the acid diffusion controllability (basicity), and thus they cannot act as a quencher, whereas they act as a quencher at unexposed portions of the resist film.

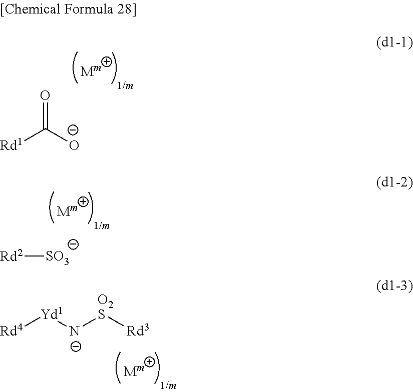

[In the formulae, Rd¹ to Rd⁴ represents cyclic groups which may have a substituent, chain-like alkyl groups which may have a substituent, or chain-like alkenyl groups which may have a substituent. Here, the carbon atom adjacent to the S atom in Rd² in General Formula (d1-2) has no fluorine atom bonded thereto. Yd¹ represents a divalent linking group or a single bond. m represents an integer of 1 or more, and each M^{m+} independently represents an m-valent organic cation.]

{Component (d1-1)}

Anion Moiety

In General Formula (d1-1), Rd¹ represents a cyclic group which may have a substituent, a chain-like alkyl group which may have a substituent, or a chain-like alkenyl group which may have a substituent, and examples thereof include the same one as R′²⁰¹.

Among these, Rd¹ is preferably an aromatic hydrocarbon group which may have a substituent, an aliphatic cyclic group which may have a substituent, or a chain-like alkyl group which may have a substituent, and it is more preferably an aromatic hydrocarbon group which may have a substituent.

Examples of the substituent which may be contained in these groups include a hydroxyl group, an oxo group, an alkyl group, an aryl group, a fluorine atom, a bromine atom, an iodine atom, a fluorinated alkyl group, a lactone-containing cyclic group, an ether bond, an ester bond, and a combination thereof.

In a case where an ether bond or an ester bond is included as the substituent, the substituent may be bonded via an alkylene group, and a linking group represented by each of General Formulae (y-a1-1) to (y-a1-5) are preferable as the substituent. It is noted that in a case where the aromatic hydrocarbon group, the aliphatic cyclic group, or the chain-like alkyl group, as Rd¹, has a linking group represented by each of General Formulae (y-a1-1) to (y-a1-7) as a substituent, in General Formulae (y-a1-1) to (y-a1-7), the group that is bonded to a carbon atom constituting the aromatic hydrocarbon group, the aliphatic cyclic group, or the chain-like alkyl group, as Rd¹, in General Formula (d1-1) is V′¹⁰¹ in General Formulae (y-a1-1) to (y-a1-7).

Suitable examples of the aromatic hydrocarbon group include a phenyl group, a naphthyl group, and a polycyclic structure (a polycyclic structure consisting of a bicyclooctane skeleton and a ring structure other than the bicyclooctane skeleton) including a bicyclooctane skeleton.

The aliphatic cyclic group is preferably a group obtained by removing one or more hydrogen atoms from a polycycloalkane such as adamantane, norbornane, isobornane, tricyclodecane, or tetracyclododecane.

The chain-like alkyl group preferably has 1 to 10 carbon atoms, and specific examples thereof include a linear alkyl group such as a methyl group, an ethyl group, a propyl group, a butyl group, a pentyl group, a hexyl group, a heptyl group, an octyl group, a nonyl group, or a decyl group, and a branched alkyl group such as a 1-methylethyl group, a 1-methylpropyl group, a 2-methylpropyl group, a 1-methylbutyl group, a 2-methylbutyl group, a 3-methylbutyl group, a 1-ethylbutyl group, a 2-ethylbutyl group, a 1-methylpentyl group, a 2-methylpentyl group, a 3-methylpentyl group, or a 4-methylpentyl group.

In a case where the chain-like alkyl group is a fluorinated alkyl group having a fluorine atom or a fluorinated alkyl group as a substituent, the fluorinated alkyl group preferably has 1 to 11 carbon atoms, more preferably 1 to 8 carbon atoms, and still more preferably 1 to 4 carbon atoms. The fluorinated alkyl group may contain an atom other than a fluorine atom. Examples of the atom other than a fluorine atom include an oxygen atom, a sulfur atom, and a nitrogen atom.

Specific examples of the preferred anion moiety for the component (d1-1) are shown below.

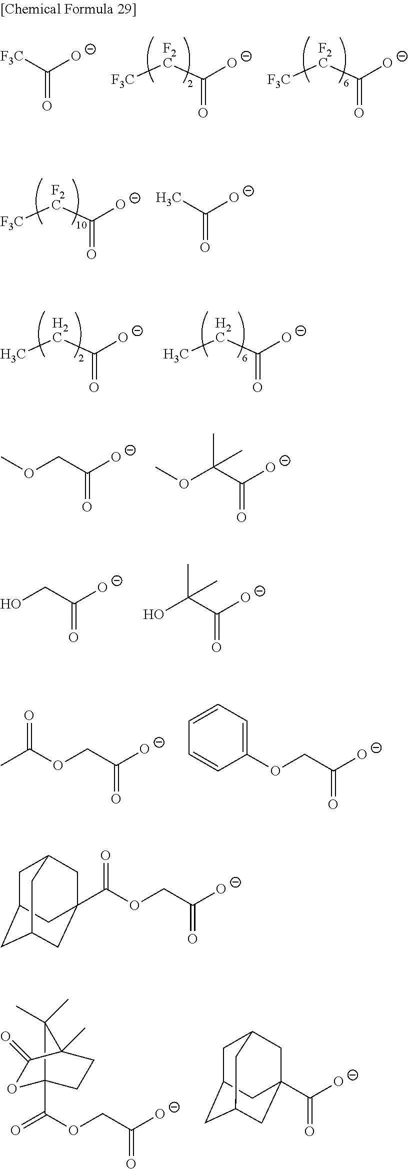

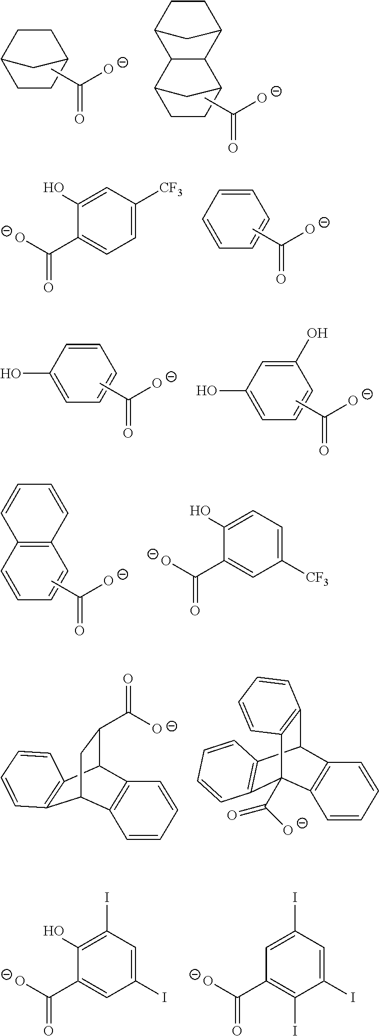

Cation Moiety

In General Formula (d1-1), M^{m+} represents an m-valent organic cation.

Suitable examples of the organic cation as M^{m+} include the same ones as the cation moiety in the compound represented by General Formula (b1-1) and the cation represented by each of General Formulae (ca-1) to (ca-3), where the same one as the cation moiety in the compound represented by General Formula (b1-1) or the cation represented by General Formula (ca-1) is more preferable, and the same cation as the cation moiety in the compound represented by General Formula (b1-1) is particularly preferable.

The component (d1-1) may be used alone or in a combination of two or more kinds thereof.

{Component (d1-2)}

Anion Moiety

In General Formula (d1-2), Rd² represents a cyclic group which may have a substituent, a chain-like alkyl group which may have a substituent, or a chain-like alkenyl group which may have a substituent, and examples thereof include the same one as R′²⁰¹.

Here, the carbon atom adjacent to the S atom in Rd² has no fluorine atom bonded thereto (the carbon atom adjacent to the S atom in Rd² is not substituted with a fluorine atom). As a result, the anion of the component (d1-2) becomes an appropriately weak acid anion, thereby improving the quenching ability of the component (D).

Rd² is preferably a chain-like alkyl group which may have a substituent or an aliphatic cyclic group which may have a substituent, and more preferably an aliphatic cyclic group which may have a substituent.

The chain-like alkyl group preferably has 1 to 10 carbon atoms and more preferably 3 to 10 carbon atoms.

The aliphatic cyclic group is more preferably a group (which may have a substituent) obtained by removing one or more hydrogen atoms from adamantane, norbornane, isobornane, tricyclodecane, tetracyclododecane, or the like; and a group obtained by removing one or more hydrogen atoms from camphor.

The hydrocarbon group as Rd² may have a substituent. Examples of the substituent include the same ones as the substituents which may be contained in the hydrocarbon group (the aromatic hydrocarbon group, the aliphatic cyclic group, or the chain-like alkyl group) as Rd¹ in General Formula (d1-1).

Specific examples of the preferred anion moiety for the component (d1-2) are shown below.

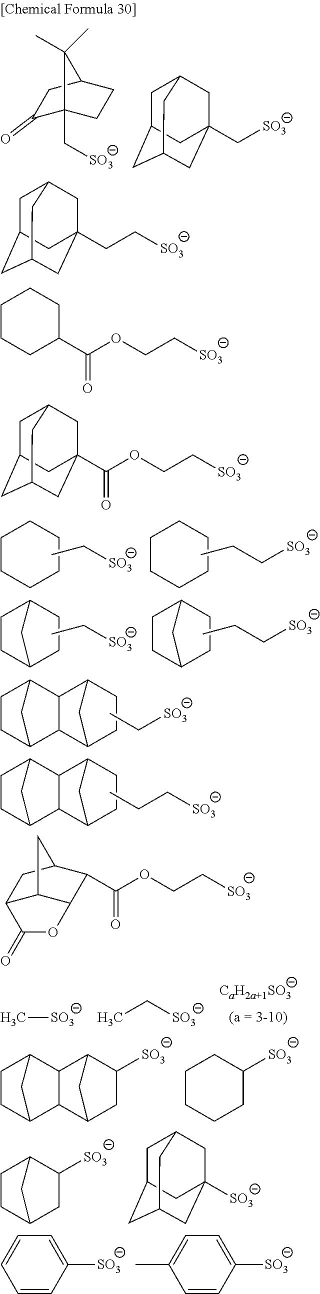

Cation Moiety

In General Formula (d1-2), M^{m+} represents an m-valent organic cation and is the same as M^{m+} in General Formula (d1-1).

The component (d1-2) may be used alone or in a combination of two or more kinds thereof.

{Component (d1-3)}

Anion Moiety

In General Formula (d1-3), Rd³ represents a cyclic group which may have a substituent, a chain-like alkyl group which may have a substituent, or a chain-like alkenyl group which may have a substituent, examples thereof include the same one as R′²⁰¹, and a cyclic group containing a fluorine atom, a chain-like alkyl group, or a chain-like alkenyl group is preferable. Among them, a fluorinated alkyl group is preferable, and the same one as the fluorinated alkyl group as Rd¹ is more preferable.

In General Formula (d1-3), Rd⁴ represents a cyclic group which may have a substituent, a chain-like alkyl group which may have a substituent, or a chain-like alkenyl group which may have a substituent, and examples thereof include the same one as R′²⁰¹.

Among them, an alkyl group which may have a substituent, an alkoxy group which may have a substituent, an alkenyl group which may have a substituent, or a cyclic group which may have a substituent is preferable.

The alkyl group as Rd⁴ is preferably a linear or branched alkyl group having 1 to 5 carbon atoms, and specific examples thereof include a methyl group, an ethyl group, a propyl group, an isopropyl group, an n-butyl group, an isobutyl group, a tert-butyl group, a pentyl group, an isopentyl group, and a neopentyl group. A part of hydrogen atoms in the alkyl group as Rd⁴ may be substituted with a hydroxyl group, a cyano group, or the like.

The alkoxy group as Rd⁴ is preferably an alkoxy group having 1 to 5 carbon atoms, and specific examples of the alkoxy group having 1 to 5 carbon atoms include a methoxy group, an ethoxy group, an n-propoxy group, an iso-propoxy group, an n-butoxy group, and a tert-butoxy group. Among these, a methoxy group and an ethoxy group are preferable.

Examples of the alkenyl group as Rd⁴ include the same one as R′²⁰¹, and a vinyl group, a propenyl group (an allyl group), a 1-methylpropenyl group, or a 2-methylpropenyl group is preferable. These groups may have an alkyl group having 1 to 5 carbon atoms or a halogenated alkyl group having 1 to 5 carbon atoms as a substituent.

Examples of the cyclic group as Rd⁴ include the same one as the cyclic group as R′²⁰¹, and an alicyclic group obtained by removing one or more hydrogen atoms from a cycloalkane such as cyclopentane, cyclohexane, adamantane, norbornane, isobornane, tricyclodecane, or tetracyclododecane, or an aromatic group such as a phenyl group or a naphthyl group is preferable. In a case where Rd⁴ represents an alicyclic group, the negative-tone resist composition can be satisfactorily dissolved in an organic solvent, thereby improving the lithography characteristics. In a case where Rd⁴ is an aromatic group, the negative-tone resist composition is excellent in light absorption efficiency and thus has good sensitivity and lithography characteristics in the lithography using EUV or the like as a light source for exposure.

In General Formula (d1-3), Yd¹ represents a single bond or a divalent linking group.

The divalent linking group as Yd¹ is not particularly limited, and examples thereof include a divalent hydrocarbon group (an aliphatic hydrocarbon group or an aromatic hydrocarbon group) which may have a substituent and a divalent linking group containing a hetero atom.

Yd¹ is preferably a carbonyl group, an ester bond, an amide bond, an alkylene group, or a combination thereof. The alkylene group is more preferably a linear or branched alkylene group, and still more preferably a methylene group or an ethylene group.

Specific examples of the preferred anion moiety for the component (d1-3) are shown below.

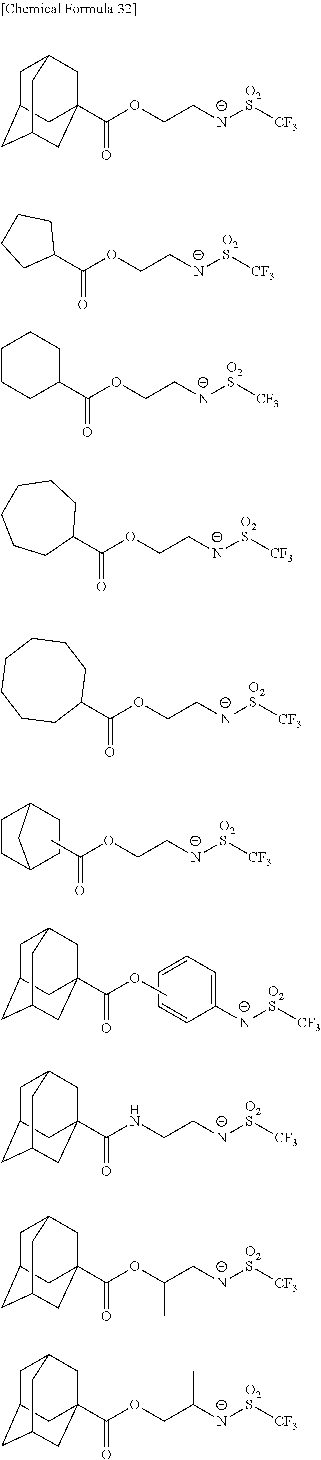

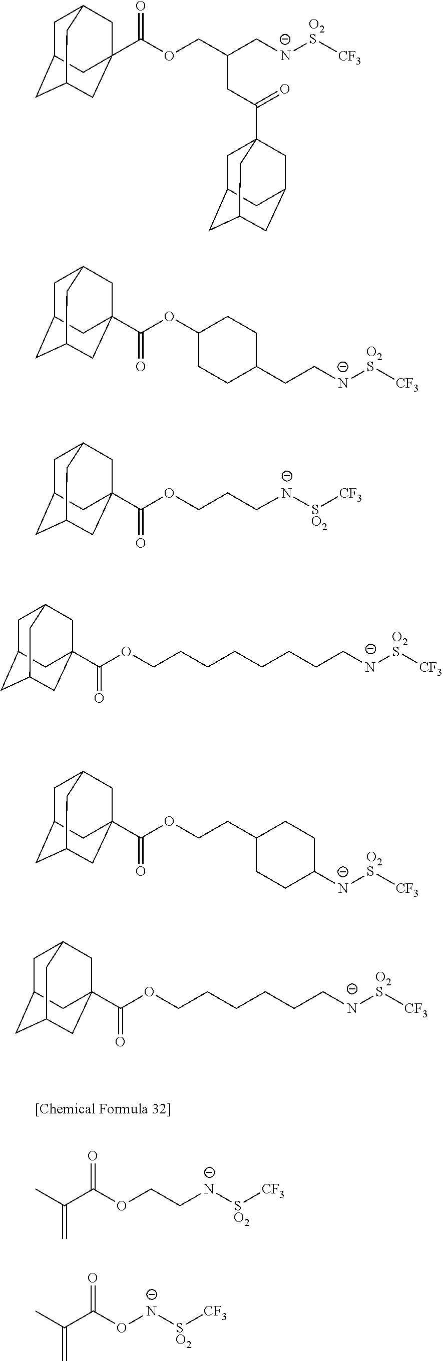

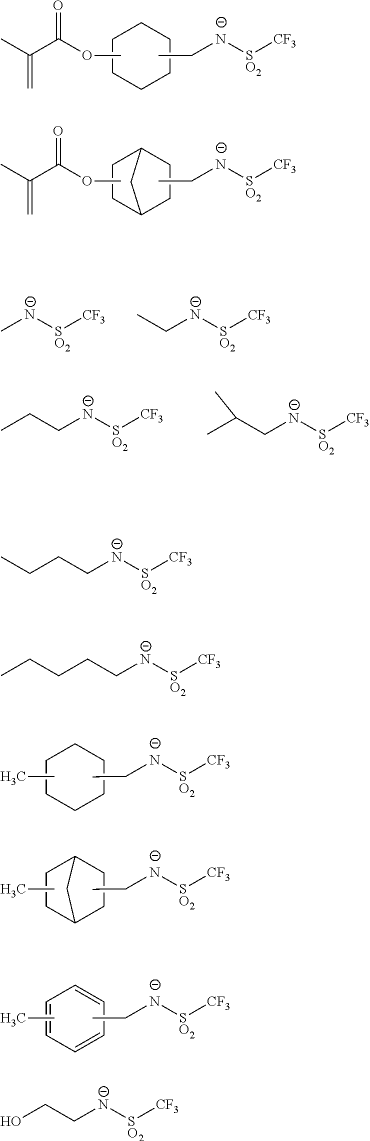

Cation Moiety

In General Formula (d1-3), M^{m+} represents an m-valent organic cation and is the same as M^{m+} in General Formula (d1-1).

The component (d1-3) may be used alone or in a combination of two or more kinds thereof.

As the component (D1), only one of the above-described components (d1-1) to (d1-3) or a combination of two or more kinds thereof may be used.

In the negative-tone resist composition according to the present embodiment, the component (D1) preferably contains the component (d1-1).

Alternatively, the component (D1) preferably contains a sulfonium salt having a fluorine atom in the cation moiety, since high sensitivity is achieved and the usability particularly for EUV is increased. Preferred examples of such a component (D1) include a compound represented by General Formula (d1-0).

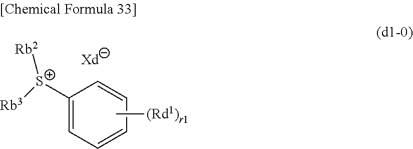

[In the formula, Rd¹ represents a fluorinated alkyl group or a fluorine atom. r1 represents an integer in a range of 1 to 5. Rd² and Rd³ each independently represent a hydrocarbon group which may have a substituent. Rd² and Rd³ may be bonded to each other to form a ring together with a sulfur atom in the formula. Rd² or Rd³ may form a condensed ring together with a sulfur atom and a benzene ring in the formula. Xd⁻ represents a counter anion].

The descriptions for Rd¹, Rd², Rd³, and r1 in Formula (d1-0) are each the same as the descriptions for Rb¹, Rb², Rb³, and q1 in Formula (b1-1).

In Formula (d1-0), Rd¹ is particularly preferably a trifluoromethyl group or a fluorine atom.

In Formula (d1-0), r1 is preferably an integer in a range of 1 to 4 and more preferably an integer in a range of 2 to 4.

In General Formula (d1-0), it is preferable that Rd² and Rd³ are a phenyl group or a naphthyl group, or Rd² and Rd³ are bonded to each other to form a ring or a condensed ring together with a sulfur atom in the formula.

Specific suitable examples of the cation moiety represented by General Formula (d1-0) include a cation represented by each of Chemical Formulae (ca-01-1) to (ca-01-17) described above.

In Formula (d1-0), Xd⁻ is a counter anion, and examples thereof include the anion moiety of the compound represented by General Formula (d1-1), the anion moiety of the compound represented by General Formula (d1-2), and the anion moiety of the compound represented by General Formula (d1-3), among which the anion moiety of the compound represented by General Formula (d1-1) is preferable.

In a case where the negative-tone resist composition contains the component (D1), the content of the component (D1) in the negative-tone resist composition is preferably 10 parts by mass or more, more preferably in a range of 15 to 45 parts by mass, and still more preferably in a range of 20 to 40 parts by mass with respect to 100 parts by mass of the component (A).

In a case where the content of the component (D1) is equal to or larger than the lower limit value of the above-described preferred range, particularly excellent lithography characteristics and a particularly excellent resist pattern shape are easily obtained. On the other hand, in a case where it is not equal to or smaller than the upper limit value of the above-described preferred range, the sensitivity is well maintained and the throughput is also excellent.

The content of the component (d1-1) in the total component (D) contained in the negative-tone resist composition according to the present embodiment is preferably 50% by mass or more, more preferably 70% by mass or more, and still more preferably 90% by mass or more, and the component (D) may consist of only the component (d1-1) (100% by mass).

Method of Producing Component (D1):

The methods of producing the components (d1-1) and (d1-2) described above are not particularly limited, and the components (d1-1) and (d1-2) can be produced by conventionally known methods.

Further, the method of producing the component (d1-3) is not particularly limited, and the component (d1-3) can be produced in the same manner as disclosed in United States Patent Application, Publication No. 2012-0149916.

In Regard to Component (D2)

The component (D) may contain a nitrogen-containing organic compound component (hereinafter, referred to as a “component (D2)”) which does not correspond to the above-described component (D1).

The component (D2) is not particularly limited as long as it acts as an acid diffusion controlling agent and does not correspond to the component (D1), and any known compound may be used. Among the above, aliphatic amines are preferable, and among the aliphatic amines, a secondary aliphatic amine or a tertiary aliphatic amine is more preferable.

The aliphatic amine is preferably an amine having one or more aliphatic groups, where the aliphatic group has 1 to 12 carbon atoms.

Examples of these aliphatic amines include an amine in which at least one hydrogen atom of ammonia (NH₃) has been substituted with an alkyl group or hydroxyalkyl group having 12 or fewer carbon atoms (alkyl amines or alkyl alcohol amines) and a cyclic amine.

Specific examples of the alkyl amine and the alkyl alcohol amine include monoalkyl amines such as n-hexyl amine, n-heptyl amine, n-octyl amine, n-nonyl amine, and n-decyl amine; dialkyl amines such as diethyl amine, di-n-propyl amine, di-n-heptyl amine, di-n-octyl amine, and dicyclohexyl amine; trialkyl amines such as trimethyl amine, triethyl amine, tri-n-propyl amine, tri-n-butyl amine, tri-n-pentyl amine, tri-n-hexyl amine, tri-n-heptyl amine, tri-n-octyl amine, tri-n-nonyl amine, tri-n-decyl amine, and tri-n-dodecyl amine; and alkyl alcohol amines such as diethanol amine, triethanol amine, diisopropanol amine, triisopropanol amine, di-n-octanol amine, and tri-n-octanol amine. Among these, trialkyl amines of 5 to 10 carbon atoms are preferable, and tri-n-pentyl amine and tri-n-octyl amine are particularly preferable.

Examples of the cyclic amine include heterocyclic compounds containing a nitrogen atom as a hetero atom. The heterocyclic compound may be a monocyclic compound (aliphatic monocyclic amine), or a polycyclic compound (aliphatic polycyclic amine).

Specific examples of the aliphatic monocyclic amine include piperidine and piperazine.

The aliphatic polycyclic amine preferably has 6 to 10 carbon atoms, and specific examples thereof include 1, 5-diazabicyclo[4.3.0]-5-nonene, 1,8-diazabicyclo[5.4.0]-7-undecene, hexamethylenetetramine, and 1,4-diazabicyclo[2.2.2]octane.

Examples of other aliphatic amines include tris(2-methoxymethoxyethyl)amine, tris{2-(2-methoxyethoxy)ethyl}amine, tris{2-(2-methoxyethoxymethoxy)ethyl}amine, tris{2-(1-methoxyethoxy)ethyl}amine, tris{2-(1-ethoxyethoxy)ethyl}amine, tris{2-(1-ethoxypropoxy)ethyl}amine, tris[2-{2-(2-hydroxyethoxy)ethoxy}ethyl]amine and triethanol amine triacetate, and triethanol amine triacetate is preferable.

In addition, as the component (D2), an aromatic amine may be used.

Examples of aromatic amines include 4-dimethylaminopyridine, pyrrole, indole, pyrazole, imidazole, and derivatives thereof, tribenzylamine, 2,6-diisopropylaniline, N-tert-butoxycarbonylpyrrolidine, and 2,6-di-tert-butylpyridine.

The component (D2) may be used alone or in a combination of two or more kinds thereof.

In a case where the negative-tone resist composition contains the component (D2), the content of the component (D2) in the negative-tone resist composition is typically in a range of 0.01 to 5 parts by mass with respect to 100 parts by mass of the component (A). By setting the content within the above range, the resist pattern shape, the post-exposure temporal stability, and the like are improved.

<<At Least One Compound (E) Selected from Group Consisting of Organic Carboxylic Acid, Phosphorus Oxo Acid, and Derivatives Thereof>>

For the purpose of preventing any deterioration in sensitivity and improving the resist pattern shape and the post-exposure temporal stability, the negative-tone resist composition according to the present embodiment may contain, as an optional component, at least one compound (E) (hereinafter, referred to as a component (E)) selected from the group consisting of an organic carboxylic acid, and a phosphorus oxo acid and a derivative thereof.

Examples of the suitable organic carboxylic acid include acetic acid, malonic acid, citric acid, malic acid, succinic acid, benzoic acid, and salicylic acid.

Examples of the phosphorus oxo acid include phosphoric acid, phosphonic acid, and phosphinic acid. Among these, phosphonic acid is particularly preferable.

Examples of the phosphorus oxo acid derivative include an ester obtained by substituting a hydrogen atom in the above-described oxo acid with a hydrocarbon group. Examples of the hydrocarbon group include an alkyl group having 1 to 5 carbon atoms and an aryl group having 6 to 15 carbon atoms.

Examples of the phosphoric acid derivative include a phosphoric acid ester such as di-n-butyl phosphate or diphenyl phosphate.

Examples of the phosphonic acid derivative include phosphonic acid esters such as dimethyl phosphonate, di-n-butyl phosphonate, phenylphosphonic acid, diphenyl phosphonate, and dibenzyl phosphonate.

Examples of the phosphinic acid derivative include phosphinic acid esters and phenylphosphinic acid.

In the negative-tone resist composition according to the present embodiment, the component (E) may be used alone or in a combination of two or more kinds thereof.

In a case where the negative-tone resist composition contains the component (E), the content of the component (E) is typically in a range of 0.01 to 10 parts by mass with respect to 100 parts by mass of the component (A).

<<Fluorine Additive Component (F)>>

The negative-tone resist composition according to the present embodiment may further contain a fluorine additive component (hereinafter, referred to as a “component (F)”) as a hydrophobic resin. The component (F) is used to impart water repellency to the resist film, where it is used as a resin different from the component (A) to improve lithography characteristics.

As the component (F), a fluorine-containing polymeric compound described in Japanese Unexamined Patent Application, First Publication No. 2010-002870, Japanese Unexamined Patent Application, First Publication No. 2010-032994, Japanese Unexamined Patent Application, First Publication No. 2010-277043, Japanese Unexamined Patent Application, First Publication No. 2011-13569, and Japanese Unexamined Patent Application, First Publication No. 2011-128226 can be mentioned.

Specific examples of the component (F) include polymers having a constitutional unit (f1) represented by General Formula (f1-1) shown below. This polymer is preferably a polymer (a homopolymer) consisting of a constitutional unit (f1) represented by General Formula (f1-1) shown below; a copolymer including a constitutional unit containing an acid decomposable group having a polarity that is increased under action of acid and the constitutional unit (f1); and a copolymer of a constitutional unit containing an acid decomposable group having a polarity that is increased under action of acid, the constitutional unit (f1), and a constitutional unit derived from acrylic acid or methacrylic acid. The constitutional unit containing an acid decomposable group having a polarity that is increased under action of acid, where the constitutional unit is copolymerized with the constitutional unit (f1), is preferably a constitutional unit derived from 1-ethyl-1-cyclooctyl (meth)acrylate or a constitutional unit derived from 1-methyl-1-adamantyl (meth)acrylate.

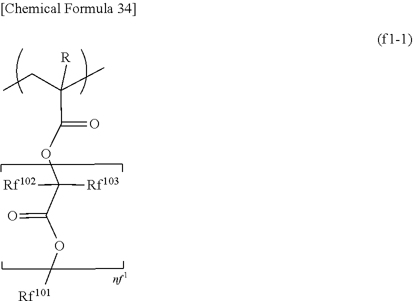

[In the formula, R has the same definition as described above. Rf¹⁰² and Rf¹⁰³ each independently represent a hydrogen atom, a halogen atom, an alkyl group having 1 to 5 carbon atoms, or a halogenated alkyl group having 1 to 5 carbon atoms, and Rf¹⁰² and Rf¹⁰³ may be the same or different from each other. nf¹ represents an integer in a range of 0 to 5 and Rf¹⁰¹ represents an organic group containing a fluorine atom.]

In General Formula (f1-1), R bonded to the carbon atom at the α-position has the same definition as described above. R is preferably a hydrogen atom or a methyl group.

In General Formula (f1-1), the halogen atom of Rf¹⁰² and Rf¹⁰³ is preferably a fluorine atom. Examples of the alkyl group having 1 to 5 carbon atoms as Rf¹⁰² and Rf¹⁰³ include the same one as the alkyl group having 1 to 5 carbon atoms as R, and a methyl group or an ethyl group is preferable. Specific examples of the halogenated alkyl group having 1 to 5 carbon atoms as Rf¹⁰² and Rf¹⁰³ include a group obtained by substituting part or all of hydrogen atoms of an alkyl group having 1 to 5 carbon atoms with a halogen atom. The halogen atom is preferably a fluorine atom. Among the above, Rf¹⁰² and Rf¹⁰³ are preferably a hydrogen atom, a fluorine atom, or an alkyl group having 1 to 5 carbon atoms and more preferably a hydrogen atom, a fluorine atom, a methyl group, or an ethyl group.

In General Formula (f1-1), nf¹ represents an integer in a range of 0 to 5, preferably an integer in a range of 0 to 3, and more preferably an integer of 1 or 2.

In General Formula (f1-1), Rf¹⁰¹ represents an organic group containing a fluorine atom and is preferably a hydrocarbon group containing a fluorine atom.

The hydrocarbon group containing a fluorine atom may be linear, branched, or cyclic, and preferably has 1 to 20 carbon atoms, more preferably 1 to 15 carbon atoms, and particularly preferably 1 to 10 carbon atoms.

In addition, in the hydrocarbon group containing a fluorine atom, 25% or more of the hydrogen atoms in the hydrocarbon group are preferably fluorinated, more preferably 50% or more are fluorinated, and particularly preferably 60% or more are fluorinated since the hydrophobicity of the resist film during immersion exposure increases.

Among them, Rf¹⁰¹ is more preferably a fluorinated hydrocarbon group having 1 to 6 carbon atoms and particularly preferably a trifluoromethyl group, —CH₂—CF₃, —CH₂—CF₂—CF₃, or —CH(CF₃)₂, —CH₂—CH₂—CF₃, or —CH₂—CH₂—CF₂—CF₂—CF₂—CF₃.

The weight average molecular weight (Mw) (in terms of the polystyrene equivalent value determined according to gel permeation chromatography) of the component (F) is preferably in a range of 1,000 to 50,000, more preferably in a range of 5,000 to 40,000, and most preferably in a range of 10,000 to 30,000. In a case where the weight average molecular weight is equal to or smaller than the upper limit value of this range, the sufficient solubility in the resist solvent is exhibited in a case of being used as a resist. On the other hand, in a case where the weight average molecular weight is equal to or larger than the lower limit value of this range, the water repellency of the resist film is excellent.

The molecular weight dispersity (Mw/Mn) of the component (F) is preferably in a range of 1.0 to 5.0, more preferably in a range of 1.0 to 3.0, and most preferably in a range of 1.0 to 2.5.

In the negative-tone resist composition according to the present embodiment, the component (F) may be used alone or in a combination of two or more kinds thereof.

In a case where the negative-tone resist composition contains the component (F), the content of the component (F) to be used is typically at a proportion of 0.5 to 10 parts by mass, with respect to 100 parts by mass of the component (A).

<<Organic Solvent Component (S)>>

The negative-tone resist composition according to the present embodiment may be produced by dissolving the resist materials in an organic solvent component (hereinafter, referred to as a “component (S)”).

The component (S) may be any organic solvent which can dissolve each of the components to be used to obtain a homogeneous solution, and any organic solvent can be appropriately selected from solvents for a chemical amplification-type resist composition, which are known in the related art, and then used.

Examples of the component (S) include lactones such as γ-butyrolactone; ketones such as acetone, methyl ethyl ketone, cyclohexanone, methyl-n-pentyl ketone, methyl isopentyl ketone, and 2-heptanone; polyhydric alcohols, such as ethylene glycol, diethylene glycol, propylene glycol and dipropylene glycol; compounds having an ester bond, such as ethylene glycol monoacetate, diethylene glycol monoacetate, propylene glycol monoacetate, and dipropylene glycol monoacetate; derivatives of polyhydric alcohols such as compounds having an ether bond, such as monoalkyl ethers (such as monomethyl ether, monoethyl ether, monopropyl ether, and monobutyl ether) of the above-described polyhydric alcohols or the above-described compounds having an ester bond and monophenyl ether [among these, propylene glycol monomethyl ether acetate (PGMEA) and propylene glycol monomethyl ether (PGME) are preferable]; cyclic ethers such as dioxane; esters such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethyl benzene, diethyl benzene, pentyl benzene, isopropyl benzene, toluene, xylene, cymene and mesitylene; and dimethylsulfoxide (DMSO).

In the negative-tone resist composition according to the present embodiment, the component (S) may be used alone or as a mixed solvent of two or more kinds thereof. Among these, PGMEA, PGME, γ-butyrolactone, EL, or cyclohexanone is preferable.

Further, a mixed solvent obtained by mixing PGMEA with a polar solvent is also preferable as the component (S). The blending ratio (in terms of mass ratio) of the mixed solvent may be appropriately determined, taking into consideration the compatibility of the PGMEA with the polar solvent, but is preferably in a range of 1:9 to 9:1 and more preferably in a range of 2:8 to 8:2.

More specifically, in a case where EL or cyclohexanone is blended as the polar solvent, the PGMEA:EL or cyclohexanone mass ratio is preferably in a range of 1:9 to 9:1 and more preferably in a range of 2:8 to 8:2. Alternatively, in a case where PGME is blended as the polar solvent, the PGMEA:PGME mass ratio is preferably in a range of 1:9 to 9:1 and more preferably in a range of 2:8 to 8:2. Furthermore, a mixed solvent of PGMEA, PGME, and cyclohexanone is also preferable.

Further, the component (S) is also preferably a mixed solvent of at least one selected from PGMEA and EL and γ-butyrolactone. In this case, as the mixing ratio, the mass ratio of the former to the latter is preferably in a range of 70:30 to 95:5.

The amount of the component (S) to be used is not particularly limited and is appropriately set, depending on a thickness of a film to be coated, to a concentration at which the component (S) can be applied onto a substrate or the like.

In the negative-tone resist composition according to the present embodiment, the solid content concentration of the negative-tone resist composition is preferably in a range of 0.1% to 10% by mass and more preferably in a range of 0.2% to 5% by mass.

In addition, in the negative-tone resist composition according to the present embodiment, the content proportion of the silicon-containing resin (A) in the solid content of the negative-tone resist composition is preferably 10% by mass or more, more preferably 20% by mass or more, still more preferably 30% to 75% by mass, particularly preferably 40% to 70% by mass, and most preferably 50% to 70% by mass.

In a case where the content proportion of the component (A) in the solid content of the negative-tone resist composition is within the above-described preferred range, the etching resistance is easily enhanced.

It is noted that the term “solid content of the negative-tone resist composition” shall refer to a content consisting of components constituting the negative-tone resist composition, excluding the organic solvent component (S).

As desired, other miscible additives can also be added to the negative-tone resist composition according to the present embodiment. For example, for improving the performance of the resist film, an additive resin, a dissolution inhibitor, a plasticizer, a stabilizer, a colorant, a halation prevention agent, and a dye can be appropriately contained therein.

For example, in the negative-tone resist composition according to the present embodiment, a hydroxystyrene resin, a resin that is a novolak resin that does not contain silicon, or the like may be used in combination, in addition to the component (A1) described above.

After dissolving the resist material in the component (S), the negative-tone resist composition according to the present embodiment may be subjected to the removal of impurities and the like by using a porous polyimide membrane, a porous polyamide-imide membrane, or the like. For example, the negative-tone resist composition may be filtered using a filter consisting of a porous polyimide membrane, a filter consisting of a porous polyamide-imide membrane, or a filter consisting of a porous polyimide membrane and a porous polyamide-imide membrane. Examples of the porous polyimide membrane and the porous polyamide-imide membrane include those described in Japanese Unexamined Patent Application, First Publication No. 2016-155121.

In the negative-tone resist composition according to the present embodiment described above, a silicon-containing polymer (a component (A1)) having a phenolic hydroxyl group, a sulfonium salt (a component (B1)) having a fluorine atom in the cation moiety, and a crosslinking agent component (a component (C)) are used in combination.

In particular, since the component (B1) in which a fluorine atom is introduced into the cation moiety is employed, sensitivity is enhanced in the formation of the resist pattern. In the negative-tone resist composition according to the present embodiment, the synergistic action of the component (B1), the components (A1), and the components (C) makes it possible to achieve high sensitivity and form a further fine-sized pattern in a good shape.

Such a negative-tone resist composition has excellent fine resolution in EUV lithography. In addition, it is possible to form a fine-sized pattern having a line width of several tens of nanometers in a good shape while suppressing roughness, which has been difficult in the related art.

In addition, since a silicon-containing polymer is used as a base material component (a base resin) for such a negative-tone resist composition, dry etching resistance is excellent.

Such a negative-tone resist composition is a resist material that makes it possible to form a silicon-containing pattern, for example, having a fine line width and reduced roughness, and that can be suitably used in the microfabrication in EUV lithography.

(Method of Forming Resist Pattern)

The method of forming a resist pattern according to the second aspect of the present invention is a method including a step (i) of forming a resist film on a support using the negative-tone resist composition according to the above-described first aspect of the present invention; a step (ii) of exposing the resist film; and a step (iii) of developing the exposed resist film to form a negative-tone resist pattern.

Examples of one embodiment of such a method of forming a resist pattern include a method of forming a resist pattern carried out as described below.

Step (i):

First, the negative-tone resist composition of the above-described embodiment is applied onto a support with a spinner or the like, and a baking (post-apply baking (PAB)) treatment is carried out, for example, at a temperature condition in a range of 80° C. to 150° C. for 40 to 120 seconds, preferably for 60 to 90 seconds to form a resist film.

Step (ii):

The selective exposure is carried out on the resist film, for example, by the exposure through a mask (mask pattern) having a predetermined pattern formed on the mask by using an exposure apparatus such as an electron beam drawing apparatus or an

EUV exposure apparatus, or direct irradiation of the resist film for drawing with an electron beam without using a mask pattern.

After the above exposure, a baking (post-exposure baking (PEB)) treatment is carried out, for example, under the temperature condition in a range of 80° C. 150° C. for a period of in a range of 40 to 120 seconds and preferably in a range of 60 to 90 seconds.

Step (iii):

Next, the exposed resist film is subjected to a developing treatment. The developing treatment is carried out using an alkali developing solution in a case of an alkali developing process, and a developing solution containing an organic solvent (organic developing solution) in a case of a solvent developing process.

In the present embodiment, a rinse treatment may be carried out after the developing treatment. As the rinse treatment, water rinsing using pure water is preferable in a case of an alkali developing process, and rinsing using a rinse liquid containing an organic solvent is preferable in a case of a solvent developing process.

In a case of a solvent developing process, after the developing treatment or the rinse treatment, the developing solution or the rinse liquid remaining on the pattern may be removed by a treatment using a supercritical fluid.

After the developing treatment or the rinse treatment, drying is conducted. As desired, baking treatment (post-baking) may be carried out following the developing treatment.

In this manner, a resist pattern can be formed.

The support is not specifically limited and a conventionally known support in the related art can be used. For example, substrates for electronic components, and such substrates having a predetermined wiring pattern formed thereon can be used. Specific examples thereof include a silicon wafer, a substrate made of a metal such as copper, chromium, iron, or aluminum; and a glass substrate. Suitable examples of the material for a wiring pattern include copper, aluminum, nickel, and gold.

In addition, the support may be a support having an inorganic and/or organic film provided on such a substrate as described above. Examples of the inorganic film include an inorganic antireflection film (an inorganic BARC). Examples of the organic film include an organic antireflection film (organic BARC) and an organic film such as a lower-layer organic film used in a multilayer resist method.

Here, the multilayer resist method is a method in which at least one layer of an organic film (lower-layer organic film) and at least one layer of a resist film (upper-layer resist film) are provided on a substrate, and a resist pattern formed on the upper-layer resist film is used as a mask to conduct patterning of the lower-layer organic film. This method is considered as being capable of forming a pattern with a high aspect ratio. More specifically, in the multilayer resist method, a desired thickness can be ensured by the lower-layer organic film, and as a result, the thickness of the resist film can be reduced, and an extremely fine pattern with a high aspect ratio can be formed.

The multilayer resist method is classified into a method in which a double-layer structure consisting of an upper-layer resist film and a lower-layer organic film is formed (double-layer resist method), and a method in which a multilayer structure having three or more layers consisting of an upper-layer resist film, a lower-layer organic film and one or more intermediate layers (thin metal film or the like) provided between the upper-layer resist film and the lower-layer organic film (triple-layer resist method).

The wavelength to be used for exposure is not particularly limited and the exposure can be carried out using radiation such as an ArF excimer laser, a KrF excimer laser, an F₂ excimer laser, an extreme ultraviolet ray (EUV), a vacuum ultraviolet ray (VUV), an electron beam (EB), an X-ray, or a soft X-ray.

The negative-tone resist composition that is used in the present embodiment is highly useful for a KrF excimer laser, an ArF excimer laser, EB, or EUV, more useful for EB or EUV, and particularly useful for EUV.

The exposure method of the resist film may be a general exposure (dry exposure) carried out in air or an inert gas such as nitrogen, or liquid immersion lithography.

The liquid immersion lithography is an exposure method in which the region between the resist film and the lens at the lowermost position of the exposure apparatus is pre-filled with a solvent (liquid immersion medium) that has a larger refractive index than the refractive index of air, and the exposure (immersion exposure) is carried out in this state.

The liquid immersion medium is preferably a solvent that exhibits a refractive index larger than the refractive index of air but smaller than the refractive index of the resist film to be exposed, and examples thereof include water, a fluorine-based inert liquid, a silicon-based solvent, and a hydrocarbon-based solvent, among which water is preferably used.

Examples of the alkali developing solution used for a developing treatment in an alkali developing process include a 0.1% to 10% by mass aqueous solution of tetramethylammonium hydroxide (TMAH).

As the organic solvent contained in the organic developing solution, which is used for a developing treatment in a solvent developing process, any organic solvent capable of dissolving the component (A) (the component (A) prior to exposure) may be appropriately selected from the conventionally known organic solvents. Specific examples of the organic solvent include polar solvents such as a ketone-based solvent, an ester-based solvent, an alcohol-based solvent, a nitrile-based solvent, an amide-based solvent, and an ether-based solvent, and hydrocarbon-based solvents.

The ketone-based solvent is an organic solvent containing C—C(═O)—C in the structure thereof. The ester-based solvent is an organic solvent containing C—C(═O)—O—C in the structure thereof. The alcohol-based solvent is an organic solvent containing an alcoholic hydroxyl group in the structure thereof. The “alcoholic hydroxyl group” indicates a hydroxyl group bonded to a carbon atom of an aliphatic hydrocarbon group. The nitrile-based solvent is an organic solvent containing a nitrile group in the structure thereof. The amide-based solvent is an organic solvent containing an amide group in the structure thereof. The ether-based solvent is an organic solvent containing C—O—C in the structure thereof.

Some organic solvents have a plurality of the functional groups which characterize the above-described solvents in the structure thereof. In such a case, the organic solvent can be classified as any type of solvent having a functional group. For example, diethylene glycol monomethyl ether can be classified as an alcohol-based solvent or an ether-based solvent.

A hydrocarbon-based solvent consists of a hydrocarbon which may be halogenated and does not have any substituent other than a halogen atom. The halogen atom is preferably a fluorine atom.

Among the above, the organic solvent contained in the organic developing solution is preferably a polar solvent and more preferably a ketone-based solvent, an ester-based solvent, or a nitrile-based solvent.

Examples of ketone-based solvent include 1-octanone, 2-octanone, 1-nonanone, 2-nonanone, acetone, 4-heptanone, 1-hexanone, 2-hexanone, diisobutyl ketone, cyclohexanone, methylcyclohexanone, phenylacetone, methyl ethyl ketone, methyl isobutyl ketone, acetylacetone, acetonylacetone, ionone, diacetonyl alcohol, acetylcarbinol, acetophenone, methyl naphthyl ketone, isophorone, propylene carbonate, γ-butyrolactone and methylamyl ketone (2-heptanone). Among these examples, the ketone-based solvent is preferably methylamyl ketone (2-heptanone).

Examples of the ester-based solvent include methyl acetate, butyl acetate, ethyl acetate, isopropyl acetate, amyl acetate, isoamyl acetate, ethyl methoxyacetate, ethyl ethoxyacetate, ethylene glycol monoethyl ether acetate, ethylene glycol monopropyl ether acetate, ethylene glycol monobutyl ether acetate, ethylene glycol monophenyl ether acetate, diethylene glycol monomethyl ether acetate, diethylene glycol monopropyl ether acetate, diethylene glycol monophenyl ether acetate, diethylene glycol monobutyl ether acetate, diethylene glycol monoethyl ether acetate, 2-methoxybutyl acetate, 3-methoxybutyl acetate, 4-methoxybutyl acetate, 3-methyl-3-methoxybutyl acetate, 3-ethyl-3-methoxybutyl acetate, propylene glycol monomethyl ether acetate, propylene glycol monoethyl ether acetate, propylene glycol monopropyl ether acetate, 2-ethoxybutyl acetate, 4-ethoxybutyl acetate, 4-propoxybutyl acetate, 2-methoxypentyl acetate, 3-methoxypentyl acetate, 4-methoxypentyl acetate, 2-methyl-3-methoxypentyl acetate, 3-methyl-3-methoxypentyl acetate, 3-methyl-4-methoxypentyl acetate, 4-methyl-4-methoxypentyl acetate, propylene glycol diacetate, methyl formate, ethyl formate, butyl formate, propyl formate, ethyl lactate, butyl lactate, propyl lactate, ethyl carbonate, propyl carbonate, butyl carbonate, methyl pyruvate, ethyl pyruvate, propyl pyruvate, butyl pyruvate, methyl acetoacetate, ethyl acetoacetate, methyl propionate, ethyl propionate, propyl propionate, isopropyl propionate, methyl 2-hydroxypropionate, ethyl 2-hydroxypropionate, methyl-3-methoxypropionate, ethyl-3-methoxypropionate, ethyl-3-ethoxypropionate, and propyl-3-methoxypropionate. Among these, the ester-based solvent is preferably butyl acetate.

Examples of the nitrile-based solvent include acetonitrile, propionitrile, valeronitrile, and butyronitrile.

As desired, the organic developing solution may have a conventionally known additive blended. Examples of the additive include surfactants. The surfactant is not particularly limited, and for example, an ionic or non-ionic fluorine-based and/or a silicon-based surfactant can be used. The surfactant is preferably a non-ionic surfactant and more preferably a non-ionic fluorine-based surfactant or a non-ionic silicon-based surfactant.

In a case where a surfactant is blended, the amount of the surfactant to be blended is typically in a range of 0.001% to 5% by mass, preferably in a range of 0.005% to 2% by mass, and more preferably in a range of 0.01% to 0.5% by mass with respect to the total amount of the organic developing solution.

The developing treatment can be carried out by a conventionally known developing method. Examples thereof include a method in which the support is immersed in the developing solution for a predetermined period (a dip method), a method in which the developing solution is cast upon the surface of the support by surface tension and maintained for a predetermined period (a puddle method), a method in which the developing solution is sprayed onto the surface of the support (spray method), and a method in which a developing solution is continuously ejected from a developing solution ejecting nozzle and applied onto a support which is scanned at a constant rate while being rotated at a constant rate (dynamic dispense method).

As the organic solvent contained in the rinse liquid used in the rinse treatment after the developing treatment in a case of a solvent developing process, an organic solvent hardly dissolving the resist pattern can be appropriately selected and used, among the organic solvents mentioned as organic solvents that are used for the organic developing solution. In general, at least one kind of solvent selected from a hydrocarbon-based solvent, a ketone-based solvent, an ester-based solvent, an alcohol-based solvent, an amide-based solvent, and an ether-based solvent is used. Among these, at least one kind of solvent selected from a hydrocarbon-based solvent, a ketone-based solvent, an ester-based solvent, an alcohol-based solvent, and an amide-based solvent is preferable, at least one kind of solvent selected from an alcohol-based solvent and an ester-based solvent is more preferable, and an alcohol-based solvent is particularly preferable.

The alcohol-based solvent used for the rinse liquid is preferably a monohydric alcohol of 6 to 8 carbon atoms, and the monohydric alcohol may be linear, branched, or cyclic. Specific examples thereof include 1-hexanol, 1-heptanol, 1-octanol, 2-hexanol, 2-heptanol, 2-octanol, 3-hexanol, 3-heptanol, 3-octanol, 4-octanol, and benzyl alcohol. Among these, 1-hexanol, 2-heptanol, and 2-hexanol are preferable, and 1-hexanol and 2-hexanol are more preferable.

As the organic solvent, one kind of solvent may be used alone, or two or more kinds of solvents may be used in combination. Further, an organic solvent other than the above-described examples or water may be mixed thereto. However, in consideration of the development characteristics, the amount of water to be blended in the rinse liquid is preferably 30% by mass or less, more preferably 10% by mass or less, still more preferably 5% by mass or less, and particularly preferably 3% by mass or less with respect to the total amount of the rinse liquid.

A conventionally known additive can be blended with the rinse liquid as necessary. Examples of the additive include surfactants. Examples of the surfactant include the same ones as those described above, the surfactant is preferably a non-ionic surfactant and more preferably a non-ionic fluorine-based surfactant or a non-ionic silicon-based surfactant.

In a case where a surfactant is blended, the amount of the surfactant to be blended is typically in a range of 0.001% to 5% by mass, preferably in a range of 0.005% to 2% by mass, and more preferably in a range of 0.01% to 0.5% by mass with respect to the total amount of the rinse liquid.

The rinse treatment using a rinse liquid (washing treatment) can be carried out by a conventionally known rinse method. Examples of the rinse treatment method include a method in which the rinse liquid is continuously ejected and applied onto the support while rotating it at a constant rate (rotational coating method), a method in which the support is immersed in the rinse liquid for a predetermined period (dip method), and a method in which the rinse liquid is sprayed onto the surface of the support (spray method).

According to the method of forming a resist pattern according to the present embodiment described above, since the negative-tone resist composition according to the first aspect described above is used, high sensitivity can be achieved, and a further fine-sized pattern can be formed in a good shape.

In particular, the method of forming a resist pattern according to the present embodiment is a method useful for subjecting the exposed resist film to alkali development to form a negative-tone resist pattern in the step (iii).

Various materials that are used in the negative-tone resist composition according to the above-described embodiment and the method of forming a resist pattern according to the above-described embodiment (for example, a resist solvent, a developing solution, a rinsing liquid, a composition for forming an antireflection film forming, and a composition for forming a top coat) preferably do not contain impurities such as a metal, a metal salt containing halogen, an acid, an alkali, and a component containing a sulfur atom or phosphorus atom. Here, examples of the impurities containing metal atoms include Na, K, Ca, Fe, Cu, Mn, Mg, A1, Cr, Ni, Zn, Ag, Sn, Pb, Li, and salts thereof. The content of the impurities contained in these materials is preferably 200 ppb or less, more preferably 1 ppb or less, still more preferably 100 parts per trillion (ppt) or less, and particularly preferably 10 ppt or less, where it is most preferable that the impurities are substantially free (below the detection limit of the measuring device).

### EXAMPLES

Hereinafter, the present invention will be described in more detail based on Examples, but the present invention is not limited to these Examples.

<Preparation of Negative-Tone Resist Composition>

### Examples 1 to 17 and Comparative Examples 1 and 2

Each of the components shown in Table 1 was mixed and dissolved to prepare a negative-tone resist composition (the solid content in the negative-tone resist composition: about 0.70% by mass) of each example.

TABLE 1

| | Component | Component | Component | Component | Component | | |
|---|---|---|---|---|---|---|---|
| | (A) | (B) | (C) | (D) | (E) | Component (S) | |
| Example | (A)-1 | (B)-1 | (C)-1 | (D)-1 | (E)-1 | (S)-1 | (S)-2 |
| 1 | [100] | [22] | [10] | [32] | [3] | [19200] | [4800] |
| Example | (A)-1 | (B)-2 | (C)-1 | (D)-2 | (E)-1 | (S)-1 | (S)-2 |
| 2 | [100] | [24] | [10] | [35] | [3] | [19200] | [4800] |
| Example | (A)-1 | (B)-3 | (C)-1 | (D)-3 | (E)-1 | (S)-1 | (S)-2 |
| 3 | [100] | [24] | [10] | [35] | [3] | [19200] | [4800] |
| Example | (A)-1 | (B)-4 | (C)-1 | (D)-4 | (E)-1 | (S)-1 | (S)-2 |
| 4 | [100] | [23] | [10] | [34] | [3] | [19200] | [4800] |
| Example | (A)-1 | (B)-5 | (C)-1 | (D)-2 | (E)-1 | (S)-1 | (S)-2 |
| 5 | [100] | [22] | [10] | [35] | [3] | [19200] | [4800] |
| Example | (A)-1 | (B)-6 | (C)-1 | (D)-3 | (E)-1 | (S)-1 | (S)-2 |
| 6 | [100] | [24] | [10] | [35] | [3] | [19200] | [4800] |
| Example | (A)-1 | (B)-3 | (C)-2 | (D)-3 | (E)-1 | (S)-1 | (S)-2 |
| 7 | [100] | [24] | [10] | [35] | [3] | [19200] | [4800] |
| Example | (A)-1 | (B)-3 | (C)-3 | (D)-3 | (E)-1 | (S)-1 | (S)-2 |
| 8 | [100] | [24] | [10] | [35] | [3] | [19200] | [4800] |
| Example | (A)-1 | (B)-3 | (C)-1 | (D)-5 | (E)-1 | (S)-1 | (S)-2 |
| 9 | [100] | [24] | [10] | [35] | [3] | [19200] | [4800] |

TABLE 2

| | Component | Component | Component | Component | Component | | |
|---|---|---|---|---|---|---|---|
| | (A) | (B) | (C) | (D) | (E) | Component (S) | |
| Example 10 | (A)-2 | (B)-3 | (C)-1 | (D)-3 | (E)-1 | (S)-1 | (S)-2 |
| | [100] | [24] | [10] | [35] | [3] | [19200] | [4800] |
| Example 11 | (A)-2 | (B)-3 | (C)-2 | (D)-3 | (E)-1 | (S)-1 | (S)-2 |
| | [100] | [24] | [10] | [35] | [3] | [19200] | [4800] |
| Example 12 | (A)-2 | (B)-3 | (C)-3 | (D)-3 | (E)-1 | (S)-1 | (S)-2 |
| | [100] | [24] | [10] | [35] | [3] | [19200] | [4800] |
| Example 13 | (A)-3 | (B)-3 | (C)-1 | (D)-3 | (E)-1 | (S)-1 | (S)-2 |
| | [100] | [24] | [10] | [35] | [3] | [19200] | 4800] |
| Example 14 | (A)-4 | (B)-3 | (C)-1 | (D)-3 | (E)-1 | (S)-1 | (S)-2 |
| | [100] | [24] | [10] | [35] | [3] | [19200] | [4800] |
| Example 15 | (A)-5 | (B)-3 | (C)-1 | (D)-3 | (E)-1 | (S)-1 | (S)-2 |
| | [100] | [24] | [10] | [35] 3 | [3] | [19200] | [4800] |
| Example 16 | (A)-6 | (B)-3 | (C)-1 | (D)-3 | (E)-1 | (S)-1 | (S)-2 |
| | [100] | [24] | [10] | [35] | [3] | [19200] | [4800] |
| Example 17 | (A)-1 | (B)-3 | (C)-2 | (D)-3 | (E)-1 | (S)-1 | (S)-2 |
| | [100] | [24] | [30] | [35] | [3] | [21600] | [5400] |
| Comparative | (A)-7 | (B)-3 | (C)-1 | (D)-3 | (E)-1 | (S)-1 | (S)-2 |
| Example 1 | [100] | [24] | [10] | [35] | [3] | [19200] | [4800] |
| Comparative | (A)-1 | (B)-7 | (C)-1 | (D)-5 | (E)-1 | (S)-1 | (S)-2 |
| Example 2 | [100] | [22] | [10] | [32] | [3] | [19200] | [4800] |

In Table 1, each abbreviation has the following meaning. The numerical values in the brackets are amounts to be blended (parts by mass: in terms of solid content).

(A)-1: A polymeric compound represented by Chemical Formula (A-1). The weight average molecular weight (Mw) in terms of standard polystyrene equivalent value, acquired by the GPC measurement, is 5,000, and the molecular weight polydispersity (Mw/Mn) is 2.3. The copolymerization compositional ratio (the ratio (the molar ratio) between constitutional units in the structural formula) is l/m=60/40.

(A)-2: A polymeric compound represented by Chemical Formula (A-2). The weight average molecular weight (Mw) in terms of standard polystyrene equivalent value, acquired by the GPC measurement, is 2,400, and molecular weight polydispersity (Mw/Mn) is 1.3. The polymerization compositional ratio (the ratio (the molar ratio) of each constitutional unit in the structural formula) is 1=100.

(A)-3: A polymeric compound represented by Chemical Formula (A-3). The weight average molecular weight (Mw) in terms of standard polystyrene equivalent value, acquired by the GPC measurement, is 2,200, and molecular weight polydispersity (Mw/Mn) is 1.3. The copolymerization compositional ratio (the ratio (the molar ratio) between constitutional units in the structural formula) is l/m=80/20.

(A)-4: A polymeric compound represented by Chemical Formula (A-4). The weight average molecular weight (Mw) in terms of standard polystyrene equivalent value, acquired by the GPC measurement, is 2,500, and the molecular weight polydispersity (Mw/Mn) is 1.5. The copolymerization compositional ratio (the ratio (the molar ratio) between constitutional units in the structural formula) is l/m/n=70/10/20.

(A)-5: A polymeric compound represented by Chemical Formula (A-5). The weight average molecular weight (Mw) in terms of standard polystyrene equivalent value, acquired by the GPC measurement, is 4,500, and molecular weight polydispersity (Mw/Mn) is 2.0. The copolymerization compositional ratio (the ratio (the molar ratio) between constitutional units in the structural formula) is l/m/n=70/10/20.

(A)-6: A polymeric compound represented by Chemical Formula (A-6). The weight average molecular weight (Mw) in terms of standard polystyrene equivalent value, acquired by the GPC measurement, is 2,900, and the molecular weight polydispersity (Mw/Mn) is 1.6. The copolymerization compositional ratio (the ratio (the molar ratio) between constitutional units in the structural formula) is l/m/n=70/10/20.

(A)-7: A polymeric compound represented by Chemical Formula (A-7). The weight average molecular weight (Mw) in terms of standard polystyrene equivalent value, acquired by the GPC measurement, is 4,700, and molecular weight polydispersity (Mw/Mn) is 2.1. The copolymerization compositional ratio (the ratio (the molar ratio) between constitutional units in the structural formula) is l/m=60/40.

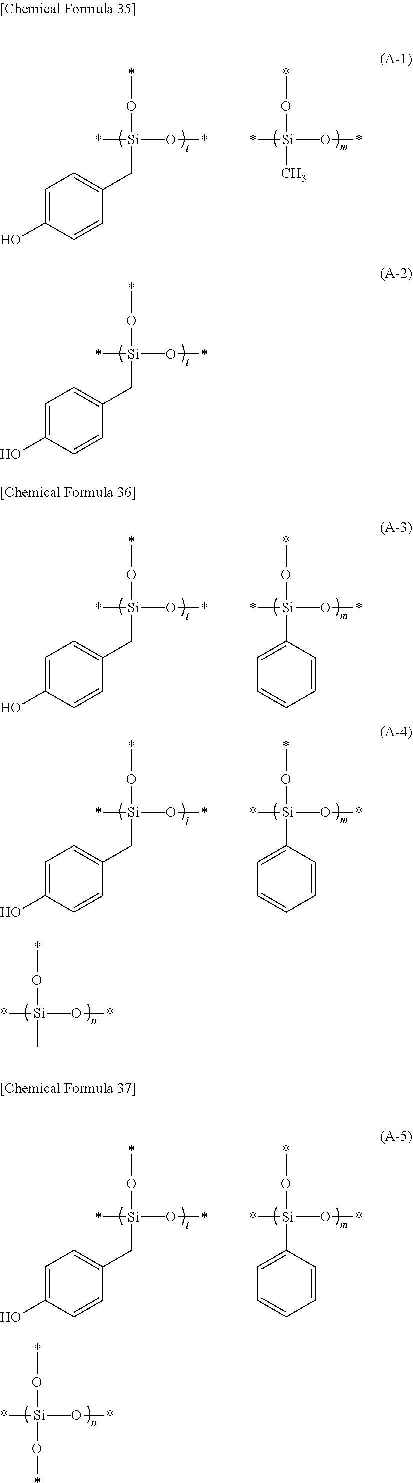

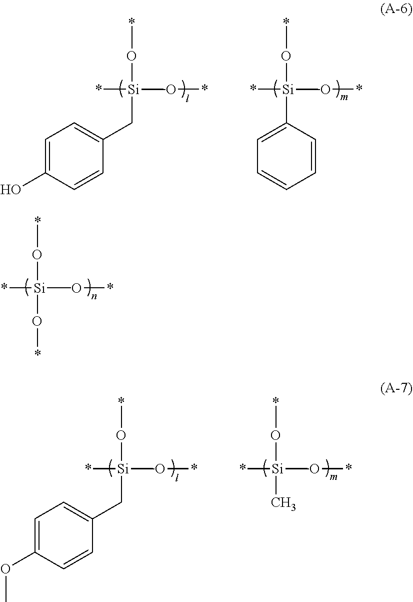

(B)-1: An acid generator consisting of a compound represented by Chemical Formula (B-1).

(B)-2: An acid generator consisting of a compound represented by Chemical Formula (B-2).

(B)-3: An acid generator consisting of a compound represented by Chemical Formula (B-3).

(B)-4: An acid generator consisting of a compound represented by Chemical Formula (B-4).

(B)-5: An acid generator consisting of a compound represented by Chemical Formula (B-5).

(B)-6: An acid generator consisting of a compound represented by Chemical Formula (B-6).

(B)-7: An acid generator consisting of a compound represented by Chemical Formula (B-7).

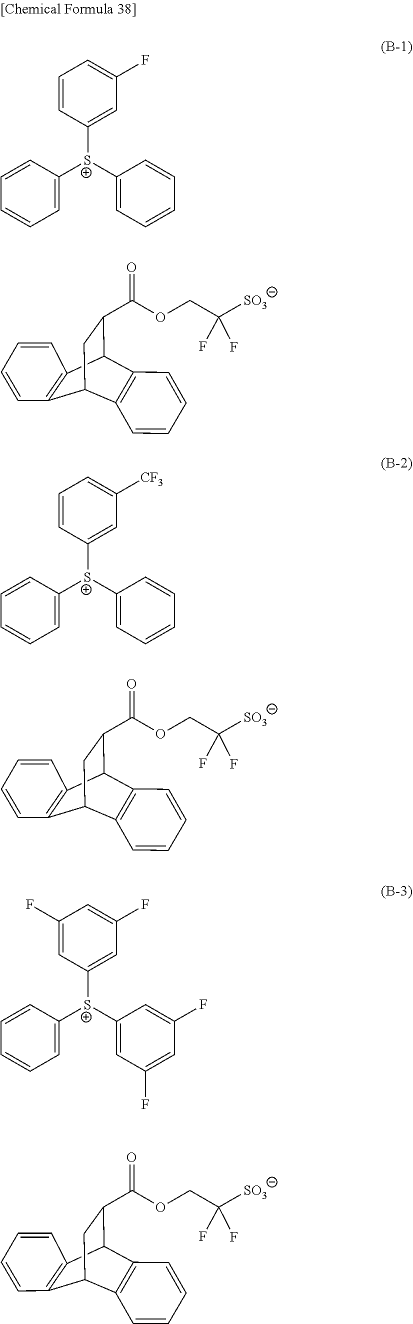

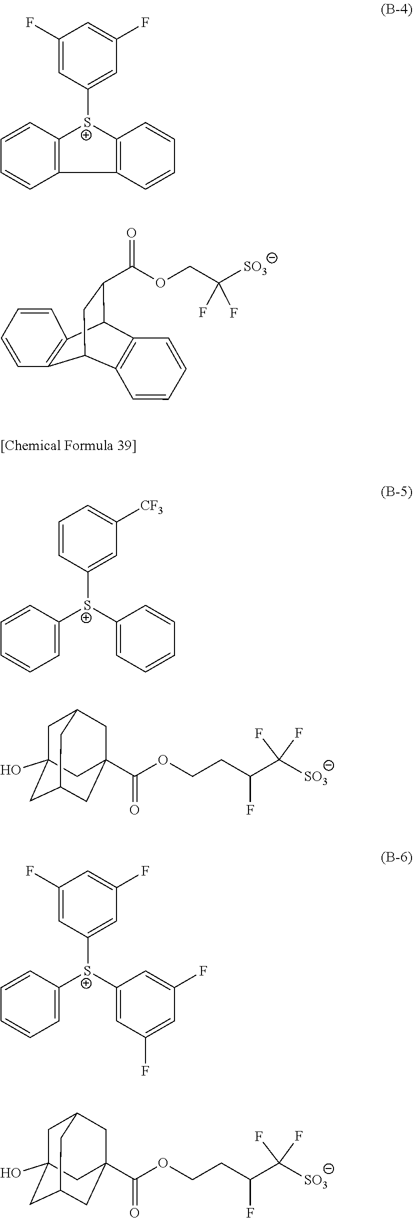

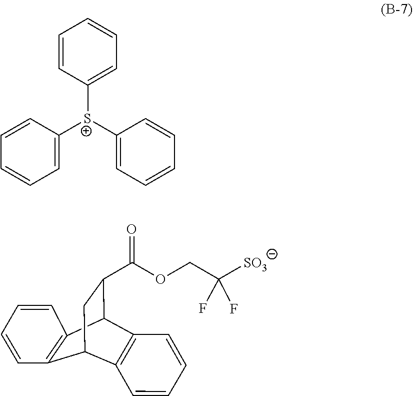

(C)-1: A crosslinking agent consisting of a compound represented by Chemical Formula (C-1).

(C)-2: A crosslinking agent consisting of a compound represented by Chemical Formula (C-2).

(C)-3: A crosslinking agent consisting of a compound represented by Chemical Formula (C-3).

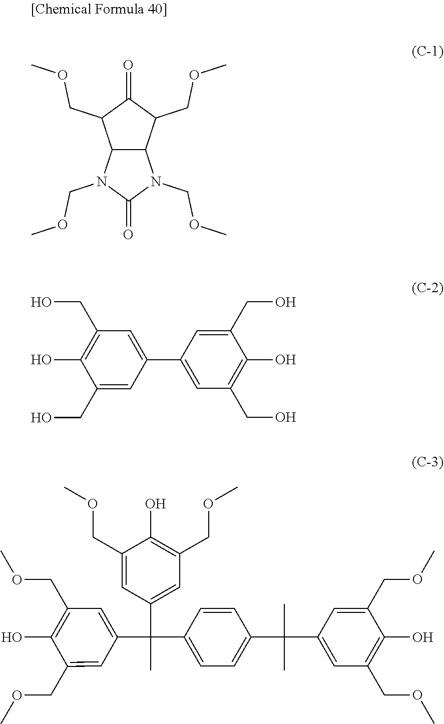

(D)-1: A photodecomposable base consisting of a compound represented by Chemical Formula (D-1).

(D)-2: A photodecomposable base consisting of a compound represented by Chemical Formula (D-2).

(D)-3: A photodecomposable base consisting of a compound represented by Chemical Formula (D-3).

(D)-4: A photodecomposable base consisting of a compound represented by Chemical Formula (D-4).

(D)-5: A photodecomposable base consisting of a compound represented by Chemical Formula (D-5).

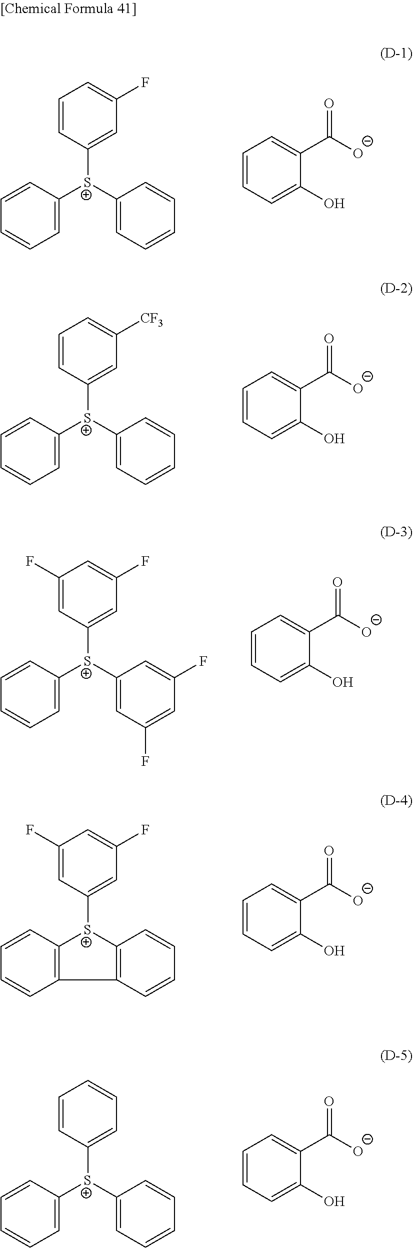

(E)-1: salicylic acid.

(S)-1: propylene glycol monomethyl ether.

(S)-2: propylene glycol monomethyl ether acetate.

<Evaluation>

A line and space pattern was formed according to the method of forming a resist pattern described below, and the optimum exposure amount (Eop) and the linewise roughness (LWR) were evaluated.

In addition, dry etching resistance was evaluated.

<<Formation of Resist Pattern>>

Step (i):

A resist organic underlayer film composition “AL412”, (manufactured by Brewer Science Inc.) was applied onto a 12-inch silicon wafer using a spin coater and sintered and dried on a hot plate at 205° C. for 60 seconds to form an organic underlayer film having a film thickness of 20 nm.

The negative-tone resist composition of each example was applied onto the organic underlayer film using a spin coater, and a pre-baking (PAB) treatment was carried out at 85° C. for 60 seconds on a hot plate to form a resist film having a film thickness of 22 nm.

Step (ii):

Next, the resist film was irradiated with EUV light (13.5 nm) through a photomask by an EUV exposure apparatus NXE3400 (manufactured by ASML Holding N.V., numerical aperture (NA)=0.33, illumination conditions: annular σ-in =0.60, σ-out=0.82).

Then, PEB treatment was carried out at 90° C. for 60 seconds.

Step (iii):

Next, in a case where the negative-tone resist compositions of Examples 1 to 16 and Comparative Examples 1 and 2 were used, alkali development was carried out with a 2.38% by mass TMAH aqueous solution (product name: NMD-3, manufactured by Tokyo Ohka Kogyo Co., Ltd.) at 23° C. for 10 seconds, and then water rinsing was carried out for 30 seconds using pure water, followed by shake-off drying.

In a case where the negative-tone resist composition of Example 17 was used, organic solvent development was carried out with butyl acetate at 23° C. for 10 seconds (without pure water rinsing).

In a case where the negative-tone resist compositions of Examples 1 to 16 were used, a line and space pattern (hereinafter, referred to as an “LS pattern”) of 1:1, having a line width of 16 nm and a pitch of 32 nm, was formed by the above-described step (i), step (ii), and step (iii).

In a case where the negative-tone resist composition of Example 17 was used, an LS pattern of 1:1, having a line width of 16 nm and a pitch of 32 nm, was formed.

In a case where the negative-tone resist composition of Comparative Example 1 was used, no resolution occurred.

In a case where the negative-tone resist composition of Comparative Example 2 was used, an LS pattern of 1:1, having a line width of 16 nm and a pitch of 32 nm, was formed.

[Evaluation of Optimum Exposure Amount (Eop)]

According to <<Formation of resist pattern>> described above, an optimum exposure amount Eop (mJ/cm²) for forming an LS pattern having a line width of 16 nm was determined. The results are shown in Tables 3 to 4 as “Eop (mJ/cm²)”.

[Evaluation of Linewise Roughness (LWR)]

For the LS pattern having a line width of 16 nm formed according to <<Formation of resist pattern>> described above, 3σ, which is a scale indicating LWR, was determined. The results are shown in Tables 3 to 4 as “LWR (nm)”.

“3σ” indicates a triple value (unit: nm) of the standard deviation (o) determined from measurement results obtained by measuring 400 line positions in the longitudinal direction of the line with a scanning electron microscope (acceleration voltage: 800V, product name: S-9380, manufactured by Hitachi High-Tech Corporation).

The smaller the value of 3σ is, the smaller the roughness in the line side wall is, which means an LS pattern having a more uniform width and a better shape was obtained.

TABLE 3

| | PAB | PEB | Eop | LWR |
|---|---|---|---|---|
| | (° C.) | (° C.) | (mJ/cm²) | (nm) |
| Example 1 | 85 | 90 | 63 | 3.50 |
| Example 2 | 85 | 90 | 60 | 3.42 |
| Example 3 | 85 | 90 | 62 | 3.22 |
| Example 4 | 85 | 90 | 64 | 3.27 |
| Example 5 | 85 | 90 | 59 | 3.65 |
| Example 6 | 85 | 90 | 59 | 3.68 |
| Example 7 | 85 | 90 | 60 | 3.15 |
| Example 8 | 85 | 90 | 59 | 3.24 |
| Example 9 | 85 | 90 | 65 | 3.67 |

TABLE 4

| | PAB | PEB | Eop | LWR |
|---|---|---|---|---|
| | (° C.) | (° C.) | (mJ/cm²) | (nm) |
| Example 10 | 85 | 90 | 67 | 3.44 |
| Example 11 | 85 | 90 | 65 | 3.19 |
| Example 12 | 85 | 90 | 65 | 3.23 |
| Example 13 | 85 | 90 | 55 | 3.66 |
| Example 14 | 85 | 90 | 58 | 3.31 |
| Example 15 | 85 | 90 | 58 | 3.24 |
| Example 16 | 85 | 90 | 60 | 3.21 |
| Example 17 | 85 | 90 | 61 | 3.88 |

| | | | |
|---|---|---|---|
| Comparative | 85 | 90 | Not resolved |
| Example 1 | | | |

| | | | | |
|---|---|---|---|---|
| Comparative | 85 | 90 | 69 | 3.97 |
| Example 2 | | | | |

From the results shown in Tables 3 to 4, it was confirmed that high sensitivity is achieved, and a fine-sized pattern is formed in a good shape since both the values of Eop and LWR are small in a case where the negative-tone resist compositions of Examples 1 to 17 are used as compared with a case where the negative-tone resist composition of Comparative Example 2 is used.

In a case where the negative-tone resist composition of Comparative Example 1 was used, the entire resist film was dissolved and removed by the alkali development, and no image was formed.

[Evaluation of Dry Etching Resistance]

The negative-tone resist composition of each of Example 1, Example 3, and Example 12 was applied onto an 8-inch silicon wafer using a spin coater, and a baking treatment was carried out at 90° C. for 60 seconds on a hot plate to form a resist film having a film thickness of 50 nm.

It is noted that the content proportion of component (A) in the solid content of the negative-tone resist composition of Example 1 is 60% by mass. The content proportion of component (A) in the solid content of the negative-tone resist composition of Example 3 is 58% by mass. The content proportion of component (A) in the solid content of the negative-tone resist composition of Example 12 is 58% by mass.

Separately, an 8% by mass propylene glycol monomethyl ether acetate solution of a novolak resin (F-1) synthesized according to a conventional method was applied onto an 8-inch silicon wafer using a spin coater, and a baking treatment was carried out at 280° C. for 60 minutes on a hot plate to form an organic film for comparing etching resistance having a film thickness of 200 nm.

Each of the formed resist film having a film thickness of 50 nm and the formed organic film for comparing etching resistance having a film thickness of 200 nm was treated with a TCP type dry etching apparatus (O₂ flow rate: 20 sccm, N₂ flow rate: 400 sccm, pressure: 12 Pa, temperature: 25° C., plasma source RF output: 600 W, bias RF output: 200 W) for 30 seconds, and the etching rate ratio of the resist film to the organic film for comparing etching resistance was calculated. The results are shown in Table 5.

In a case where the etching rate ratio is less than 0.1, it can be said that the dry etching resistance is good.

TABLE 5

| | Etching rate ratio |
|---|---|
| Example 1 | 0.045 |
| Example 3 | 0.048 |
| Example 12 | 0.059 |

From the results shown in Table 5, it was found that in a case where the negative-tone resist compositions of Example 1, Example 3, and Example 12 are used, the etching rate ratio is a value less than 0.1.

From this, it was confirmed that the negative-tone resist compositions of Example 1, Example 3, and Example 12, to which the present invention has been applied, have good dry etching resistance.

While preferred Examples according to the present invention have been described above; however, the present invention is not limited to these Examples. Additions, omissions, substitutions, and other modifications can be made without departing from the gist or scope of the present invention. Accordingly, the present invention is not to be considered as being limited by the foregoing description and is only limited by the scope of the appended claims.

While preferred embodiments of the invention have been described and illustrated above, it should be understood that these are exemplary of the invention and are not to be considered as limiting. Additions, omissions, substitutions, and other modifications can be made without departing from the scope of the invention. Accordingly, the invention is not to be considered as being limited by the foregoing description and is only limited by the scope of the appended claims.

What is claimed is:

1. A negative-tone resist composition comprising:
a silicon-containing resin (A);
an acid generator component (B) that generates acid upon exposure; and
a crosslinking agent component (C),
wherein the silicon-containing resin (A) contains a silicon-containing polymer (A1) having a phenolic hydroxyl group, and
the acid generator component (B) contains a sulfonium salt (B1) having a fluorine atom in a cation moiety.

2. The negative-tone resist composition according to claim 1, wherein the silicon-containing polymer (A1) is a polysiloxane having a repeating structure of a constitutional unit represented by General Formula (a1-1), 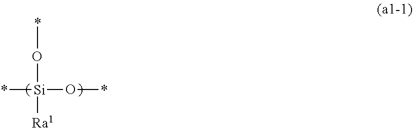
wherein Ra¹ is a hydrocarbon group having a phenolic hydroxyl group, and * represents a bonding site.

3. The negative-tone resist composition according to claim 1, wherein the sulfonium salt (B1) is a compound represented by General Formula (b1-1), 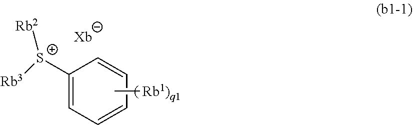
wherein Rb¹ represents a fluorinated alkyl group or a fluorine atom, q1 represents an integer in a range of 1 to 5, Rb² and Rb³ each independently represent a hydrocarbon group which may have a substituent, Rb² and Rb³ may be bonded to each other to form a ring together with a sulfur atom in the formula, Rb² or Rb³ may form a condensed ring together with a sulfur atom and a benzene ring in the formula, and Xb⁻ is a counter anion.

4. The negative-tone resist composition according to claim 1, further comprising a base component (D) which controls diffusion of the acid generated from the acid generator component (B) upon exposure.

5. The negative-tone resist composition according to claim 4, wherein the base component (D) contains a sulfonium salt (D1) having a fluorine atom in a cation moiety.

6. The negative-tone resist composition according to claim 1, wherein a content of the silicon-containing resin (A) in a solid content of the negative-tone resist composition is 10% by mass or more.

7. A method of forming a resist pattern, comprising:
forming a resist film on a support using the negative-tone resist composition according to claim 1;
exposing the resist film; and
developing the exposed resist film to form a negative-tone resist pattern.

8. The method of forming a resist pattern according to claim 7, wherein the resist film is exposed with an extreme ultraviolet ray (EUV).
